(19) United States
(12) Patent Application Publication
(10) Pub. No.: US 2024/0312788 A1
(43) Pub. Date: Sep. 19, 2024

(54) SEMICONDUCTOR FIN CUT PROCESS AND STRUCTURES FORMED THEREBY

(71) Applicant: Taiwan Semiconductor Manufacturing Company, Ltd., Hsin-Chu (TW)

(72) Inventors: Shin-Li WANG, Pingtung County (TW); Szu-Ping LEE, Changhua County (TW); Zu-Yin LIU, Taipei City (TW); You-Ting LIN, Miaoli County (TW); Jiun-Ming KUO, Taipei City (TW); Chun-Hung LEE, Hsinchu City (TW); Yuan-Ching PENG, Hsinchu (TW)

(21) Appl. No.: 18/452,004

(22) Filed: Aug. 18, 2023

Related U.S. Application Data
(60) Provisional application No. 63/490,255, filed on Mar. 15, 2023.

(51) Int. Cl. H01L 21/3065; H01L 29/06; H01L 29/423; H01L 29/66; H01L 29/775; H01L 29/786

(52) U.S. Cl. CPC H01L 21/3065; H01L 29/0673; H01L 29/42392; H01L 29/66439; H01L 29/66545; H01L 29/775; H01L 29/78696

(57) ABSTRACT

A method includes forming a fin protruding from a substrate, the fin including an epitaxial stack over a fin base and a hard mask layer over the epitaxial stack, the epitaxial stack including first and second semiconductor layers of different material compositions, performing a first etching process to etch the hard mask layer, the first etching process including applying a first combination of etchants, performing a second etching process to etch the epitaxial stack, the second etching process including applying a second combination of etchants, and performing a third etching process to etch the fin base, the third etching process including applying a third combination of etchants. The first, second, and third combinations of etchants are different from each other.

### PRIORITY DATA

This application claims priority to U.S. Provisional Patent Application No. 63/490,255 filed on Mar. 15, 2023, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

To enhance the device controllability and reduce the substrate surface area occupied by the planar devices, the semiconductor industry has progressed into nanometer technology process nodes in pursuit of higher device density, higher performance, and lower costs. Challenges from both fabrication and design issues have resulted in the development of three-dimensional designs, such as a multi-gate field effect transistor (FET), including a fin field effect transistor (FinFET) and a gate-all-around (GAA) field effect transistor (FET). In a FinFET, a gate electrode is adjacent to three side surfaces of a channel region with a gate dielectric layer interposed therebetween. Because the gate structure surrounds the fin on three surfaces (i.e., the top surface and the opposite lateral surfaces), the transistor essentially has three gates controlling (one gate at each of the top surface and the opposite lateral surfaces) the current through the fin or channel region. The fourth side of the bottom of the channel is far away from the gate electrode and thus is not under close gate control. In contrast, in a GAA FET, all side surfaces (i.e. the top surface, the opposite lateral surfaces, and the bottom surface) of the channel region are surrounded by the gate electrode, which allows for fuller depletion in the channel region and results in reduced short-channel effect due to steeper sub-threshold current swing (SS) and smaller drain induced barrier lowering (DML). As transistor dimensions are continually scaled down to sub-micron technology nodes, further improvements of the FinFETs and/or GAA FETs are required.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 illustrates an etching apparatus, in accordance with some embodiments of the present disclosure.

FIG. 2 illustrates a flowchart of an example method for making a semiconductor device, in accordance with some embodiments of the present disclosure.

FIGS. 3A, 4A, 5A, 6A, 7A, 8A, 9A, 10A, 11A, 12A, 13A, 14A, 15A, 16A, 17A, 18A, and 19A illustrate perspective views of a semiconductor device constructed according to the method in FIG. 2, in accordance with some embodiments.

FIGS. 3B, 4B, 5B, 6B, 7B, 8B, 9B, 10B, 11B, 12B, 13B, 14B, 15B, 16B, 17B, 18B, and 19B illustrate cross-sectional views in an X-Z plane of a portion of the semiconductor device in respective perspective views during fabrication processes according to the method of FIG. 2, in accordance with some embodiments of the present disclosure.

FIGS. 3C, 4C, 5C, 6C, 7C, 8C, 9C, 10C, 11C, 12C, 13C, 14C, 15C, 16C, 17C, 18C, and 19C illustrate cross-sectional views in a Y-Z plane of a portion of the semiconductor device in respective perspective views during fabrication processes according to the method of FIG. 2, in accordance with some embodiments of the present disclosure.

FIGS. 20, 21, 22, 23, 24, 25, 26, 27, 28, 29, and 30 illustrate cross-sectional views in a X-Z plane regarding a region of the semiconductor device during fabrication processes according to the method of FIG. 2, in accordance with some embodiments of the present disclosure.

FIG. 31 illustrates some etching parameters applied in multiple etching steps of a fin cut process, in accordance with some embodiments of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

Some processes of manufacturing semiconductor devices, such as, fin field effect transistors (FinFETs) and/or gate-all-around (GAA) field effect transistors (FETs) involve forming all fins in the device by lithography processes. After all fins are formed, a number of fins or certain portions of selected fins are removed by a fin cut process. For example, a fin cut process may remove a portion of a fin and thus “cuts” the otherwise continuous fin into two separated fins. Isolation features, such as shallow trench isolation (STI) features, are formed where the fin is cut and protect the fin edges formed by the fin cut process. A conventional fin cut process may produce a fin edge profile that is slanted. With the ever-decreasing device dimensions along the advancement of process nodes, the isolation features protecting the fin edge may be very thin and vulnerable to etching processes during the manufacturing process. Isolation features deposited at a bottom of a slanted fin edge is relatively easier to be etched away and cause the fin edge to be exposed. If the fin edge loses the protection from the isolation features, epitaxial growth may occur from the exposed fin edge and cause short to adjacent device features.

The present disclosure provides a process flow that includes a fin cut process. The fin cut process includes multiple etching steps that produce a substantially vertical fin edge profile. The multiple etching processes may be performed in-situ.

The disclosed structure and the method of making the same are applicable to a semiconductor structure having FETs with a three-dimensional structure, such as fin FETs (FinFETs) formed on fin active regions, and FETs with vertically-stacked multiple channels, such as gate-all-around (GAA) structure. For the purposes of simplicity, the present disclosure uses GAA transistors as an example. Those of ordinary skill in the art should appreciate that they may readily use the present disclosure as a basis for designing or modifying other processes and structures (such as FinFETs) for carrying out the same purposes and/or achieving the same advantages of the embodiments introduced herein.

The multiple etching steps in the fin cut process may each be a dry etch where the fin is exposed to a plasma source and one or more etchant gases. The etch may be an inductively coupled plasma (ICP) etch, a transformer coupled plasma (TCP) etch, an electron cyclotron resonance (ECR) etch, a reactive ion etch (RIE), or the like.

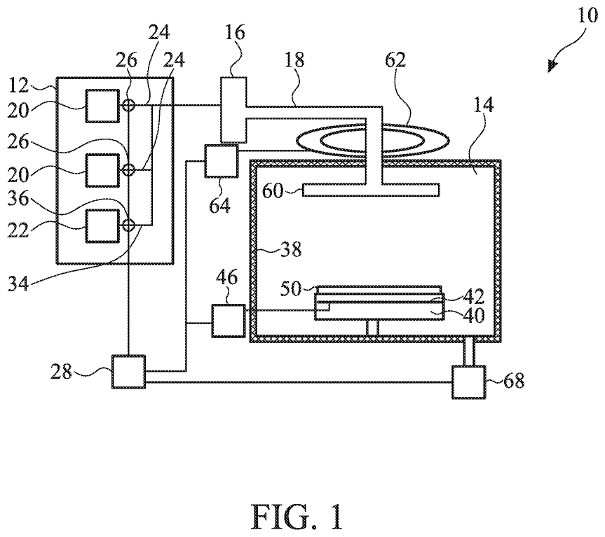

FIG. 1 illustrates an exemplary etching system (etching apparatus) 10 that may be suitable to perform the fin cut process. In an embodiment the etching system 10 may comprise an etchant delivery system 12 that may deliver one or more gaseous etchants to an etching chamber 14. The etchant delivery system 12 supplies the various desired etchants to the etching chamber 14 through an etchant controller 16 and a manifold 18. The etchant delivery system 12 may also help to control the flow rate of the etchant into the etching chamber 14 by controlling the flow and pressure of a carrier gas through the etchant delivery system 12.

In an embodiment the etchant delivery system 12 may include a plurality of etchant suppliers 20 along with a carrier gas supply 22. Additionally, while only two etchant suppliers 20 are illustrated in FIG. 1, this is done merely for clarity, as any suitable number of etchant suppliers 20, such as one etchant supplier 20 for each etchant desired to be used within the etching system 10. For example, in an embodiment in which five separate etchants will be utilized, there may five separate etchant suppliers 20.

Each of the individual etchant suppliers 20 may be a vessel, such as a gas storage tank, that is located either locally to the etching chamber 14 or remotely from the etching chamber 14. Alternatively, the etchant supplier 20 may be a facility that independently prepares and delivers the desired etchants. Any suitable source for the desired etchants may be utilized as the etchant supplier 20, and all such sources are fully intended to be included within the scope of the embodiments.

In an embodiment the individual etchant suppliers 20 supply an etchant to the etchant controller 16 through first lines 24 with first valves 26. The first valves 26 are controlled by a controller 28 that controls and regulates the introduction of the various etchants and carrier gases to the etching chamber 14.

A carrier gas supply 22 may supply a desired carrier gas, or diluent gas, that may be used to help push or “carry” the various desired etchants to the etching chamber 14. The carrier gas may be an inert gas or other gas that does not react with the etchant itself or with by-products from the etchant's reactions. For example, the carrier gas may be nitrogen (N₂), helium (He), argon (Ar), combinations of these, or the like, although other suitable carrier gases may alternatively be utilized.

The carrier gas supply 22, or diluent supply, may be a vessel, such as a gas storage tank, that is located either locally to the etching chamber 14 or remotely from the etching chamber 14. Alternatively, the carrier gas supply 22 may be a facility that independently prepares and delivers the carrier gas to the etchant controller 16. Any suitable source for the carrier gas may be utilized as the carrier gas supply 22, and all such sources are fully intended to be included within the scope of the embodiments. The carrier gas supply 22 may supply the desired carrier gas to the etchant controller 16 through a second line 34 with a second valve 36 that connects the carrier gas supply 22 to the first lines 24. The second valve 36 is also controlled by the controller 28 that controls and regulates the introduction of the various etchants and carrier gases to the etching chamber 14. Once combined, the lines may be directed towards the etchant controller 16 for a controlled entry into the etching chamber 14.

The etching chamber 14 may be any desired shape that may be suitable for dispersing the etchant and contacting the etchant with the wafer 50. In the embodiment illustrated in FIG. 1, the etching chamber 14 has a cylindrical sidewall and a bottom. However, the etching chamber 14 is not limited to a cylindrical shape, and any other suitable shape, such as a hollow square tube, an octagonal shape, or the like, may alternatively be utilized. Furthermore, the etching chamber 14 may be surrounded by an etchant chamber housing 38 made of material that is inert to the various process materials. As such, while the etchant chamber housing 38 may be any suitable material that can withstand the chemistries and pressures involved in the etching process, in an embodiment the etchant chamber housing 38 may be steel, stainless steel, nickel, aluminum, alloys of these, combinations of these, and the like.

Additionally, the etching chamber 14 and the mounting platform 40 may be part of a cluster tool system (not shown). The cluster tool system may be used in conjunction with an automated handling system in order to position and place the wafer 50 into the etching chamber 14 prior to the etching process, position and hold the wafer 50 during the etching processes, and remove the wafer 50 from the etching chamber 14 after the etching processes.

Within the etching chamber 14 is located a mounting platform 40 in order to position and control the wafer 50 during the etching process. The mounting platform 40 may hold the wafer 50 using a combination of clamps, vacuum pressure, and/or electrostatic forces, and may also include heating and cooling mechanisms in order to control the temperature of the wafer 50 during the processes. In a particular embodiment the mounting platform 40 may comprise four cooling zones, such as an inner temperature zone, a middle inner temperature zone, a middle outer temperature zone, and an outer temperature zone (not individually illustrated) in order to heat and cool the wafer 50 during the etching process. The various temperature zones may use gaseous or liquid heat transfer materials to precisely control the temperature of the wafer 50 during the etching process, although any suitable number of heating or cooling zones may alternatively be utilized.

The mounting platform 40 may additionally comprise a first electrode 42 coupled to a first RF generator 46. The first electrode 42 may be electrically biased by the first RF generator 46 (under control of the controller 28) at a RF voltage during the etching process. By being electrically biased, the first electrode 42 is used to provide a bias to the incoming etchants and assist to ignite them into a plasma. Additionally, the first electrode 42 is also utilized to maintain the plasma during the etching process by maintaining the bias.

Furthermore, while a single mounting platform 40 is illustrated in FIG. 1, this is merely intended for clarity and is not intended to be limiting. Rather, any number of mounting platforms 40 may additionally be included within the etching chamber 14. As such, multiple semiconductor substrates may be etched during a single etching process.

Additionally, the etching chamber 14 comprises a showerhead 60. In an embodiment the showerhead 60 receives the various etchants from the manifold 18 and helps to disperse the various etchants into the etching chamber 14. The showerhead 60 may be designed to evenly disperse the etchants in order to minimize undesired process conditions that may arise from uneven dispersal. In an embodiment the showerhead 60 may have a circular design with openings dispersed evenly around the showerhead 60 to allow for the dispersal of the desired etchants into the etching chamber 14.

The etching chamber 14 also comprises an upper electrode 62, for use as a plasma generator. In an embodiment the plasma generator may be a transformer coupled plasma generator and may be, e.g., a coil. The coil may be attached to a second RF generator 64 that is utilized to provide power to the upper electrode 62 (under control of the controller 28) in order to ignite the plasma during introduction of the reactive etchants.

However, while the upper electrode 62 is described above as a transformer coupled plasma generator, embodiments are not intended to be limited to a transformer coupled plasma generator. Rather, any suitable method of generating the plasma, such as inductively coupled plasma systems, magnetically enhanced reactive ion etching, electron cyclotron resonance, a remote plasma generator, or the like, may alternatively be utilized. All such methods are fully intended to be included within the scope of the embodiments.

The etching chamber 14 may also be connected to a vacuum pump 68. In an embodiment the vacuum pump 68 is under the control of the controller 28, and may be utilized to control the pressure within the etching chamber 14 to a desired pressure. Additionally, once the etching process is completed, the vacuum pump 68 may be utilized to evacuate the etching chamber 14 in preparation for removal of the wafer 50.

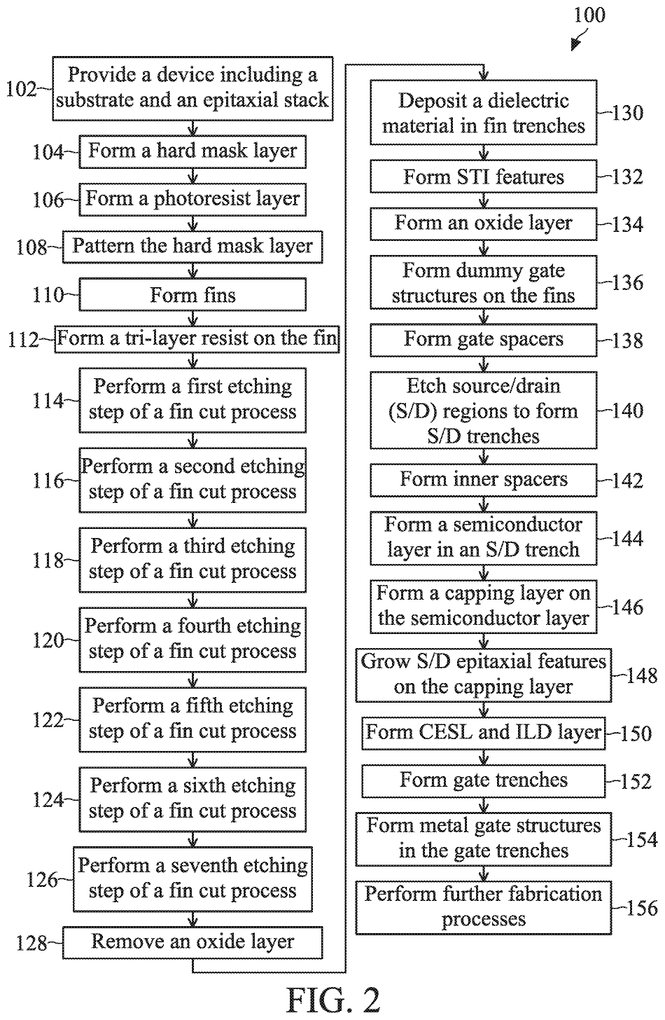

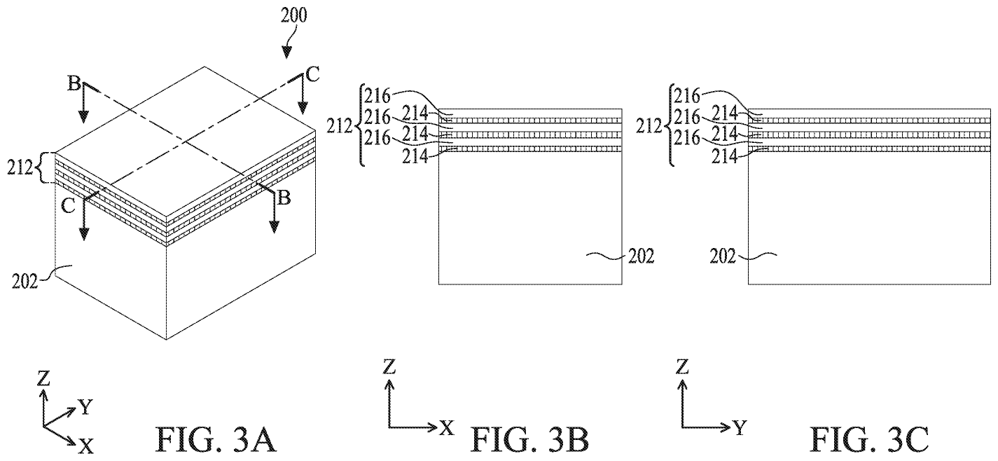

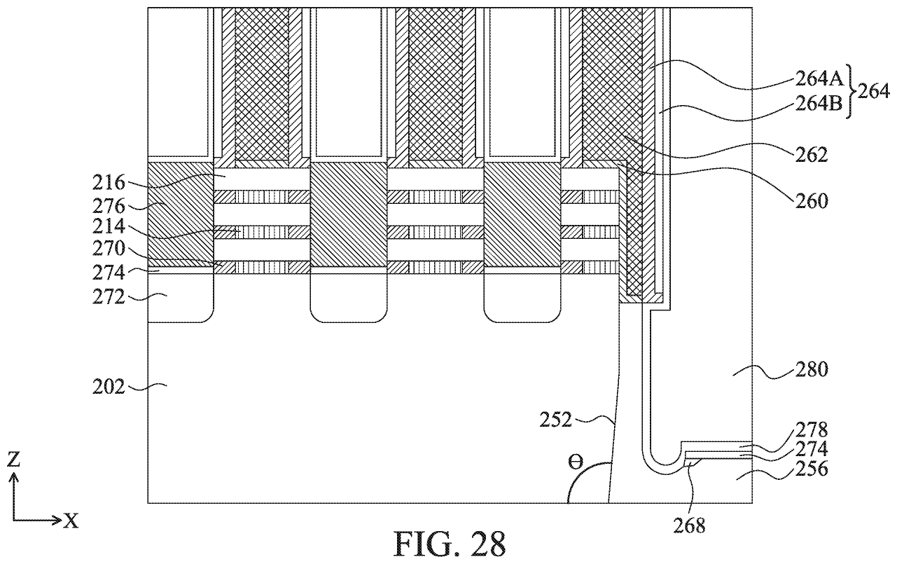

FIG. 2 illustrates a flow chart of a method 100 for fabricating a semiconductor device according to various embodiments of the present disclosure. Additional processing is contemplated by the present disclosure. Additional operations can be provided before, during, and after method 100, and some of the operations described can be moved, replaced, or eliminated for additional embodiments of method 100. FIG. 2 is described below in conjunction with FIG. 3A through FIG. 30 that illustrate various perspective and cross-sectional views of a semiconductor device (or device) 200 at various steps of fabrication according to the method 100, in accordance with some embodiments.

In some embodiments, the device 200 is a portion of an IC chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, memory devices, other suitable components, or combinations thereof. FIGS. 3A through 30 have been simplified for the sake of clarity to better understand the inventive concepts of the present disclosure. Additional features can be added in the device 200, and some of the features described below can be replaced, modified, or eliminated in other embodiments of the device 200.

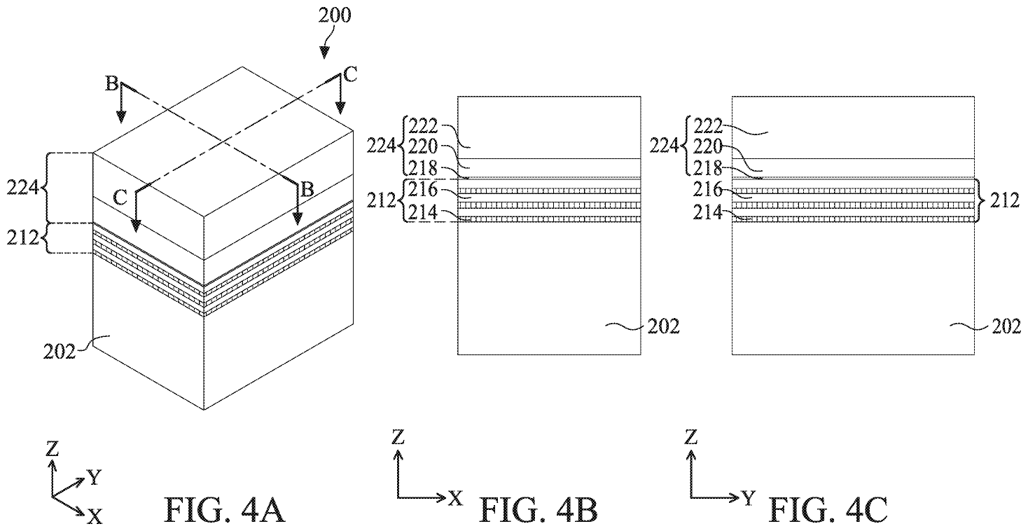

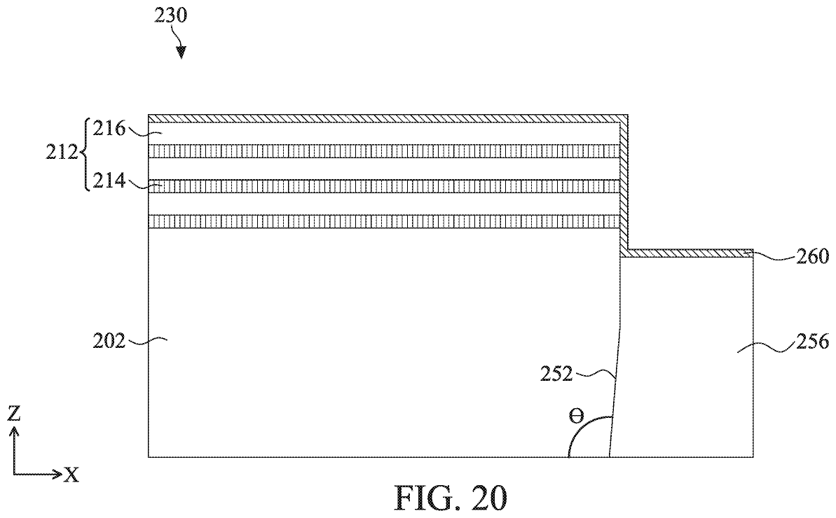

At operation 102, the method 100 (FIG. 2) provides a device 200 having a substrate 202 and an epitaxial stack 212 disposed on the substrate 202, as shown in FIGS. 3A-3C. FIG. 3A illustrates a perspective view of the device 200, and FIGS. 3B and 3C illustrate cross-sectional views of the device 200, in portion, along the B-B line and the C-C line in FIG. 3A, respectively. Particularly, the B-B line is a cut along the lengthwise direction of to-be-formed semiconductor fins (direction “X” or X-direction) and the C-C line is a cut in a direction perpendicular to the lengthwise direction of to-be-formed semiconductor fins (direction “Y” or Y-direction). Thus, FIG. 3B is a cross-sectional view in an X-Z plane, and FIG. 3C is a cross-sectional view in a Y-Z plane. The B-B lines and C-C lines in FIGS. 4A through 19C are similarly configured. FIGS. 20 through 30 also illustrate cross-sectional views of a region of the device 200 in the X-Z plane.

In some embodiments, the substrate 202 is a silicon-on-insulator (SOI) substrate. Semiconductor-on-insulator substrates can be fabricated using separation by implantation of oxygen (SIMOX), wafer bonding, and/or other suitable methods. In an alternative embodiment, the substrate 202 is a bulk silicon substrate (i.e., including bulk single-crystalline silicon). The substrate 202 may include other semiconductor materials in various embodiment, such as germanium, silicon carbide, gallium arsenide, gallium phosphide, indium phosphide, indium arsenide, indium antimonide, SiGe, GaAsP, AlInAs, AlGaAs, GaInAs, GaInP, GaInAsP, or combinations thereof.

The epitaxial stack 212 includes epitaxial layers 214 of a first composition interposed by epitaxial layers 216 of a second composition. The first and second compositions can be different. In an embodiment, the epitaxial layers 214 are SiGe layers and the epitaxial layers 216 are Si layers. However, other embodiments are possible including those that provide for a first composition and a second composition having different oxidation rates and/or etch selectivity. As described further below, the epitaxial layers 216 or portions thereof form channel regions of the device 200. In the depicted embodiment, the epitaxial stack 212 includes three epitaxial layers 214 and three epitaxial layers 216 configured to form three semiconductor layer pairs disposed over the substrate 202, each semiconductor layer pair having a respective first epitaxial layer 214 and a respective second epitaxial layer 216. After undergoing subsequent processing, such configuration will result in the device 200 having three channel layers. However, the present disclosure contemplates embodiments where the epitaxial stack 212 includes more or less semiconductor layers, for example, depending on a number of channels desired for the device 200 (e.g., a GAA transistor) and/or design requirements of the device 200. For example, the epitaxial stack 212 can include two to ten epitaxial layers 214 and two to ten epitaxial layers 216. In an alternative embodiment where the device 200 is a FinFET device, the epitaxial stack 212 is simply one layer of a semiconductor material, such as one layer of Si.

By way of example, the epitaxial stack 212 may be epitaxially grown on the substrate 202. The epitaxial growth be performed by a molecular beam epitaxy (MBE) process, a metalorganic chemical vapor deposition (MOCVD) process, and/or other suitable epitaxial growth processes. In some embodiments, the epitaxially grown layers, such as the epitaxial layers 216, include the same material as the overlaying semiconductor layer 208, such as Si. In some embodiments, either of the epitaxial layers 214 and 216 may include a different material than the overlaying semiconductor layer 208. In furtherance of the embodiments, either of the epitaxial layers 214 and 216 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the epitaxial layers 214 and 216 may be chosen based on providing differing oxidation and etch selectivity properties. In some embodiments, the epitaxial layers 214 have a first etch rate to an etchant and the epitaxial layers 216 have a second etch rate to the etchant, where the second etch rate is less than the first etch rate. In some embodiments, the epitaxial layers 214 have a first oxidation rate and the epitaxial layers 216 have a second oxidation rate, where the second oxidation rate is less than the first oxidation rate. In the depicted embodiment, the epitaxial layers 214 and the epitaxial layers 216 include different materials, constituent atomic percentages, constituent weight percentages, thicknesses, and/or characteristics to achieve desired etching selectivity during an etching process, such as an etching process implemented to form suspended channel layers in channel regions of the device 200. For example, where the epitaxial layers 214 include silicon germanium and the epitaxial layers 216 include silicon, a silicon etch rate of the epitaxial layers 216 is less than a silicon germanium etch rate of the epitaxial layers 214 for given etchant. In some embodiments, the epitaxial layers 214 and the epitaxial layers 216 can include the same material but with different constituent atomic percentages to achieve the etching selectivity and/or different oxidation rates. For example, the epitaxial layers 214 and the epitaxial layers 216 can include silicon germanium, where the epitaxial layers 214 have a first silicon atomic percent and/or a first germanium atomic percent and the epitaxial layers 216 have a second, different silicon atomic percent and/or a second, different germanium atomic percent. The present disclosure contemplates that the epitaxial layers 214 and the epitaxial layers 216 include any combination of semiconductor materials that can provide desired etching selectivity, desired oxidation rate differences, and/or desired performance characteristics (e.g., materials that maximize current flow), including any of the semiconductor materials disclosed herein.

In some embodiments, the epitaxial layer 214 has a thickness ranging from about 3 nm to about 6 nm. In furtherance of the embodiments, the epitaxial layers 214 in the epitaxial stack 212 may be substantially uniform in thickness. In yet some alternative embodiments, the bottommost epitaxial layer 214 may be thicker than other upper epitaxial layers 214, such as about 20% to about 50% thicker. In some embodiments, the epitaxial layer 216 has a thickness ranging from about 4 nm to about 12 nm. In furtherance of the embodiments, the epitaxial layers 216 in the epitaxial stack 212 are substantially uniform in thickness. As described in more detail below, in the illustrated embodiment, the epitaxial layers 216 serve as channel layers for a GAA transistor and the thickness is chosen based on device performance considerations. The epitaxial layers 214 serve to reserve a spacing (or referred to as a gap) between adjacent channel structures for a GAA transistor and the thickness is chosen based on device performance considerations as well. Accordingly, the epitaxial layers 214 are also referred to the sacrificial layers 214, and the epitaxial layers 216 are also referred to as the channel layers 216 or the nanostructures 216.

At operation 104, the method 100 (FIG. 2) forms a pad oxide layer 218 over the epitaxial stack 212, a nitride layer 220 over the pad oxide layer 218, and an oxide layer 222 over the nitride layer 220, as shown in FIGS. 4A-4C. The pad oxide layer 218 enhances the adhesion of the nitride layer 220 to the epitaxial stack 212. The pad oxide layer 218, the nitride layer 220, and the oxide layer 222 collectively form a hard mask layer 224. In some embodiments, the pad oxide layer 218 is made of silicon oxide, which can be formed by a thermal oxidation process; the nitride layer 220 is made of silicon nitride (SiN), which can be formed by chemical vapor deposition (CVD), including low pressure CVD (LPCVD) and plasma enhanced CVD (PECVD), physical vapor deposition (PVD), atomic layer deposition (ALD), or other suitable process; the oxide layer 222 may be formed by CVD, PVD, ALD, or other suitable process. In some embodiments, a thickness of the pad oxide layer 218 may range from about 1 nm to about 5 nm, and a thickness of the nitride layer 220 may range from about 10 nm to about 50 nm. Further, the nitride layer 220 is thicker than the pad oxide layer 218. In some embodiments, a thickness of the oxide layer 222 may range from about 10 nm to about 50 nm in some embodiments. In the illustrated embodiment, the oxide layer 222 is thicker than the nitride layer 220; alternatively, the oxide layer 222 may be thinner than the nitride layer 220.

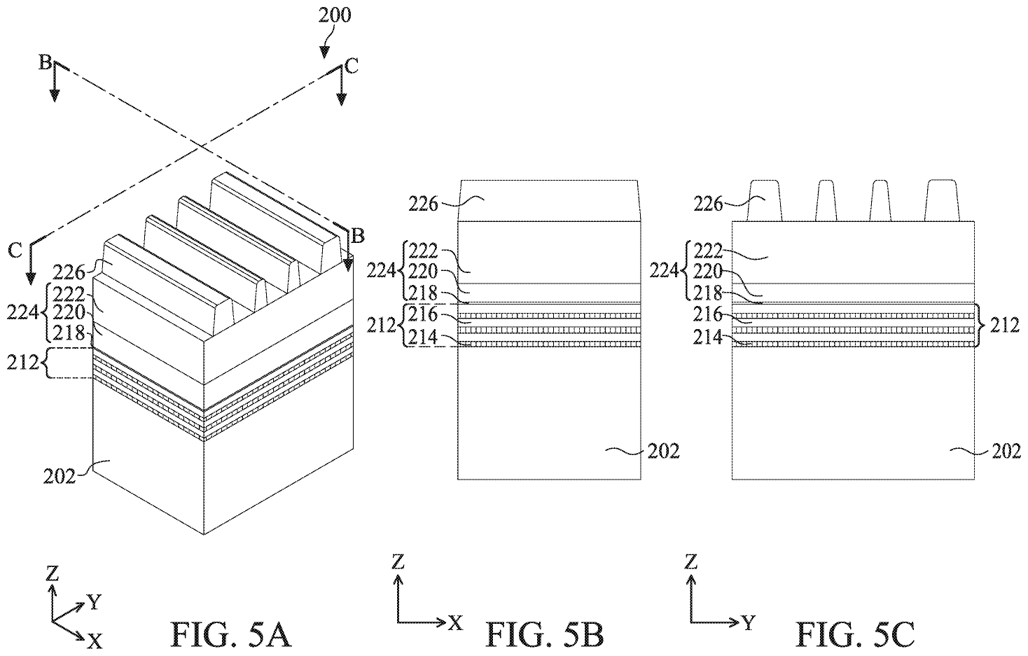

At operation 106, the method 100 (FIG. 2) deposits a photoresist layer 226 over the hard mask layer 224, as shown in FIGS. 5A-5C. The photoresist layer 226 is patterned to define fins. The photoresist layer 226 is patterned using patterning techniques including, for example, electron-beam lithography, photolithography, or any other suitable process. In other embodiments, a mandrel layer is deposited instead of the photoresist layer 226. The mandrel layer may include materials such as silicon oxide, silicon nitride, or silicon oxynitride. Other suitable materials may be used. One way of forming the mandrel layer includes using a deposition process, such as a chemical vapor deposition (CVD) or a physical vapor deposition (PVD) process, and a patterning process, such as photolithography.

In some embodiments, the lithography operations of the photoresist layer include coating a photosensitive resist film over a substrate, exposing the resist film deposited over the substrate by an optical lithography tool or an electron beam writer, and developing the exposed resist film to form a resist pattern for an ion trim process or an etching process. The resist may include a positive tone resist or a negative tone resist. The resist film may include a single layer resist film or a multiple layer resist film.

In some embodiments, the coating the resist film over the substrate includes performing a dehydration operation before applying the resist film over the substrate. The dehydration operation enhances the adhesion of the resist film to the substrate in some embodiments. The dehydration operation may include baking the substrate at a high temperature for a duration of time, or applying a chemical such as hexamethyldisilizane (HMDS) to the substrate. Other embodiments also include a soft bake (SB) process to drive solvent out of the resist film and increase the mechanical strength of the resist film. Antireflective coating, such as the bottom antireflective coating (BARC) or a top antireflective coating (TARC) is applied below or above the resist layers in some embodiments.

Exposing the resist film deposited over the substrate includes using an optical exposing tool or a charged particle exposing tool. The optical lithography tool may include an I-line, a deep ultraviolet (DUV), an extreme ultraviolet (EUV) tool, or ArF and KrF laser tools. The charged particle exposing tool includes an electron beam or an ion beam tool. The optical exposing tool includes using a mask in some embodiments. The mask may be a binary mask (BIM), a super binary mask (SBIM), or a phase shift mask (PSM), which includes an alternative phase shift mask (alt. PSM) or an attenuated phase shift mask (att. PSM). Developing the exposed resist film includes a post exposure bake (PEB), a post development bake (PDB) process, or a combination thereof in some embodiments.

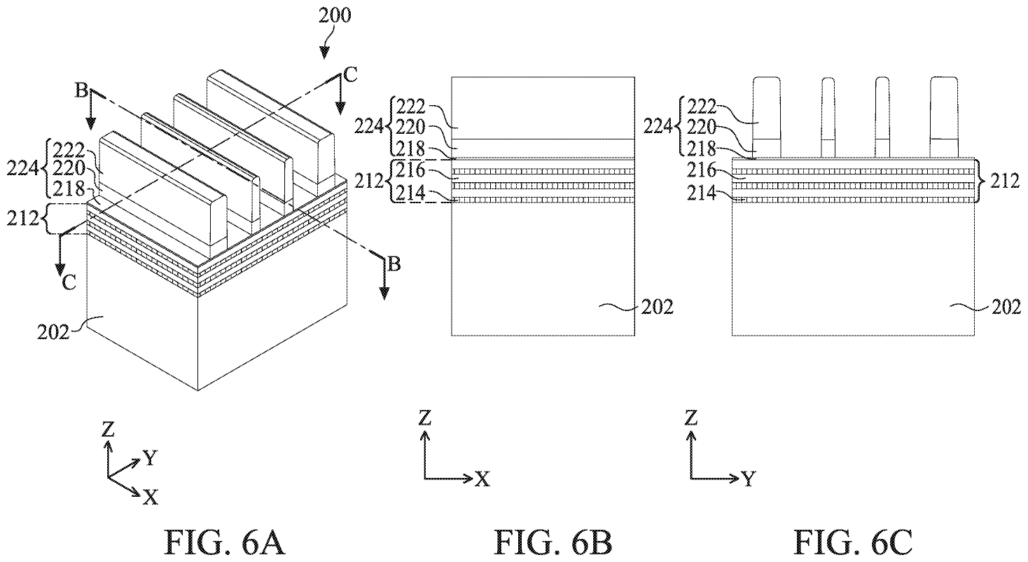

At operation 108, the method 100 (FIG. 2) performs an etching operation on the oxide layer 222 and the nitride layer 220 using the patterned photoresist layer 226 (or a mandrel layer) as an etch mask, as shown in FIGS. 6A-6C. The etching operation removes portions of the oxide layer 222 and the nitride layer 220 exposed by the patterned photoresist layer 226, and thereby a patterned hard mask layer 224 is obtained. The pad oxide layer 218 serves as an etch stop layer, protecting the top surface of the epitaxial layer 212 from being damaged by the etching operation. The photoresist layer 226 is removed by a suitable photoresist stripping or plasma ashing operation. For example, in some embodiments, a suitable solvent is used to remove the photoresist layer 226. In some other embodiments, the photoresist layer 226 is removed by oxygen plasma ashing operation.

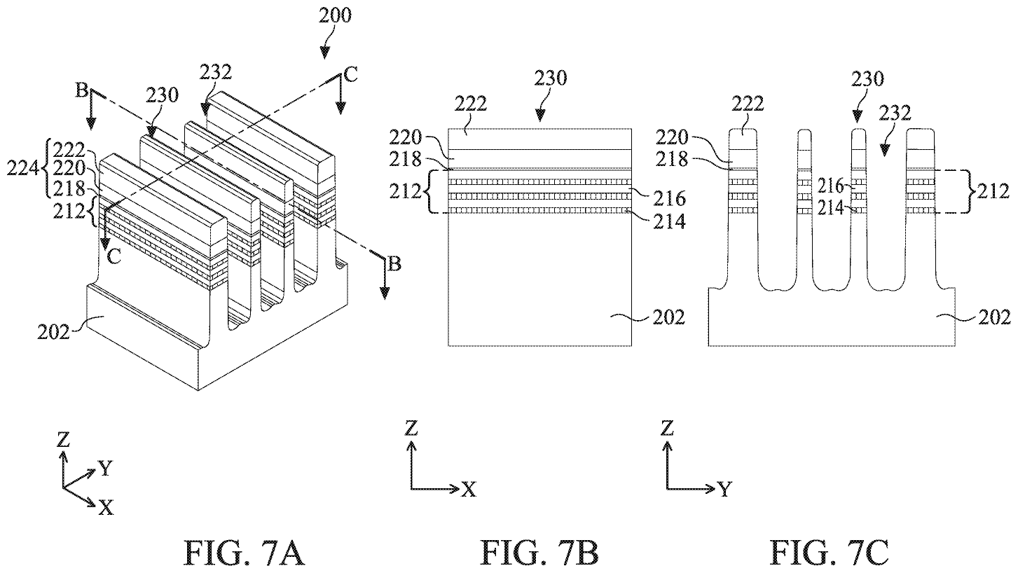

At operation 110, the method 100 (FIG. 2) patterns the epitaxial stack 212 to form semiconductor fins 230 (also referred to as fins 230) and trenches 232 between adjacent fins 230 using the patterned hard mask layer 224 as an etch mask, as shown in FIGS. 7A-7C. In various embodiments, each of the fins 230 includes a top portion of the interleaved epitaxial layers 214 and 216 and a bottom portion that is formed by patterning a top portion of the substrate 202. The bottom portion of a fin 230 is also referred to as a fin base or a mesa. That is, in the illustrated embodiment, a fin base or mesa includes the patterned top portion of the substrate 202. In some embodiments, the patterning of the epitaxial stack 212 is performed using a wet etchant such as, but not limited to, ammonium hydroxide (NH₄OH), tetramethylammonium hydroxide (TMAH), ethylenediamine pyrocatechol (EDP), or potassium hydroxide (KOH) solutions. In other embodiments, the etching operation is performed using a wet etchant such as, but not limited to, HF:HNO₃ solution, HF:CH₃COOH:HNO₃, or H₂SO₄ solution and HF:H₂O₂:CH₃COOH. In some embodiments, a dry etching operation is used. The dry etching operation may use an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. In some embodiments, a combination of dry etching techniques and wet etching techniques are used to perform the etching operations.

In some other embodiments the fins 230 are patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. The sacrificial layer may include materials such as silicon oxide, silicon nitride, or silicon oxynitride. Other suitable materials may be used. One way of forming the sacrificial layer includes using a deposition process, such as a chemical vapor deposition (CVD) or a physical vapor deposition (PVD) process. Spacers are formed alongside the patterned sacrificial layer using a self-aligned process. The sacrificial layer is then removed, and the remaining spacers may then be used to pattern the fins.

Still referring to FIGS. 7A-7C, each of the fins 230 protrudes upwardly in the Z-direction above the substrate 202 and extends lengthwise in the X-direction. In FIGS. 7A-7C, four (4) fins 230 are spaced apart along the Y-direction. But the number of the fins is not limited to four, and may be as small as one, two, three, or more than four. The fins 220 may have a uniform fin width along the Y-direction. As shown in further detail below, a fin cut process is performed to “cut” one of the fins 230 into two separated segments.

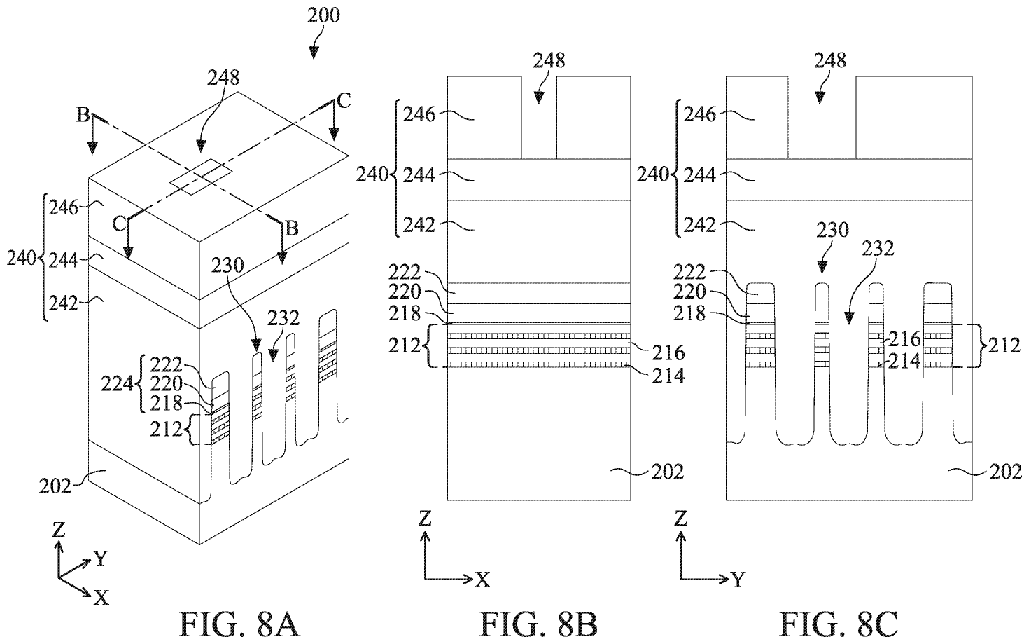

At operation 112, the method 100 (FIG. 2) forms a tri-layer resist 240 over the device 200, as shown in FIGS. 8A-8C. The tri-layer resist 240 includes a bottom layer (BL) 242 deposited in the trenches 232 and over the fins 230, a middle layer (ML) 244 deposited over the bottom layer 242, and a photosensitive layer 246 deposited over the middle layer 244 and patterned to form an opening 248. The opening 248 is overlying a middle portion of a fin 230 and thereby defines a fin cut area. The bottom layer 242 and the middle layer 244 collectively define an anti-reflective layer.

The photosensitive layer 246 is a photoresist in some embodiments. The bottom layer 242 is an organic layer in some embodiments. In some embodiments, the bottom layer 242 has a planarized upper surface. In some embodiments, the bottom layer 242 includes a polymer. In some embodiments, the middle layer 244 includes a silicon-containing inorganic polymer. In other embodiments, the middle layer 244 includes a siloxane polymer. In other embodiments, the middle layer 244 includes silicon oxide (e.g., spin-on glass (SOG)), silicon nitride, silicon oxynitride, polycrystalline silicon, a metal-containing organic polymer material that contains metal such as titanium, titanium nitride, aluminum, and/or tantalum; and/or other suitable materials.

Some conventional approaches to manufacturing semiconductor devices involve utilizing a single etching operation to etch through various layers, such as the middle layer and the bottom layer, in order to remove a portion of the targeted area. However, this single etching operation fails to adequately account for the unique characteristics of each material layer, including differences in composition, thickness, and geometry. Consequently, the resulting structure may fall short of ideal expectations. A notable issue arising from a single etching operation is the formation of slanted sidewalls in the etched bottom layer. When this pattern is subsequently transferred to the fin, the edges of the fin may also become slanted. Such slanted fin cut profile can introduce complications. For instance, isolation features are typically formed to safeguard the edges of the fin. Unfortunately, when the fin edge is slanted, these isolation features located at the bottom of the slanted fin edge may be too thin and become susceptible to being etched away in subsequent manufacturing steps. This loss of protection can lead to epitaxial growth from the exposed fin edges, potentially causing short circuits with adjacent device features. To address these concerns, an alternative fin cut process is presented. This process involves multiple etching steps, specifically tailored to target each material layer on and above the fin individually. By doing so, the formation of slanted fin cut edges can be substantially avoided, thereby mitigating device defects. Further details on this multi-step etching approach will be explored in subsequent discussions.

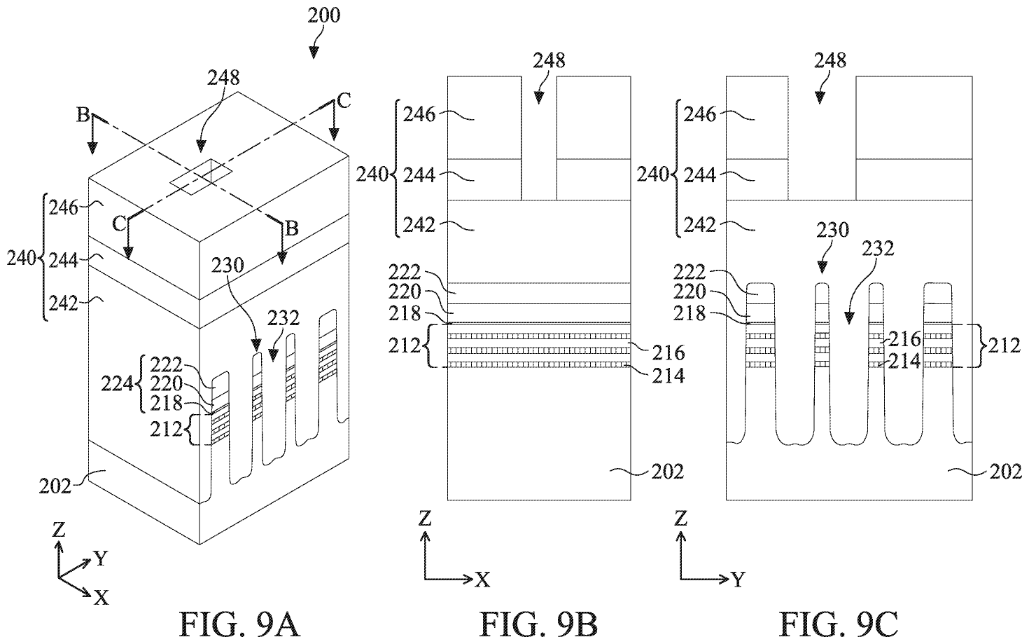

At operation 114, the method 100 (FIG. 2) performs a first etching step (first etching process) of the fin cut process by using the etching system 10, which extends the opening 248 through the middle layer 244, as shown in FIGS. 9A-9C. Once the device 200 has been placed in the etching system 10 and is attached to the mounting platform 40, the controller 28 may initiate the first etching step by connecting one or more of the etchant suppliers 20 and another one of the carrier gas supply 22 to the etching chamber 14 to introduce a first etching combination of etchants. While the precise etchants utilized are dependent at least in part upon the materials chosen for the middle layer 244, in an embodiment the first etching combination of etchants may comprise a combination of CH₂F₂ and CF₄ along with a diluent such as helium (He). In an embodiment, a pressure in the etching chamber 14 is set to between about 10 mtorr and about 150 mtorr.

Within the etching chamber 14, the first etching combination of etchants may be ignited into plasma. In an embodiment the first etching combination of etchants may be ignited by the controller 28 sending a signal to the second RF generator 64 to supply to the upper electrode 62 a power of between about 300 W and about 1000 W. Additionally, the transformer-coupled capacitive tuning (TCCT) parameter may be set to between about 0 and about 2. This range for the TCCT parameter in the first etching step is not arbitrary, which safeguards uniformity in extending the opening 248 through the middle layer 244. The controller 28 may also send a signal to the first RF generator 46 in order to supply an AC voltage to the first electrode 42. In an embodiment the RF generator 46 supplies an AC voltage of between about 200 V and about 600 V.

In an embodiment of the first etching step, the plasma is a continuously turned-on plasma. Once the plasma has been ignited, the process conditions as described above are maintained in order to expose the middle layer 244 to the plasma generated within the etching chamber 14. In an embodiment the process conditions are maintained and the middle layer 244 is exposed for a time period of between about 10 seconds and about 60 seconds.

Once the etching process has been performed to a desired length, such as etching through the middle layer 244, the controller 28 may stop the flow of the first etching combination of etchants from entering the etching chamber 14, stopping the first etching step. Once the etching process has been stopped, the conditions within the etching chamber 14 may be modified either prior to or during the introduction of a second etching combination of etchants.

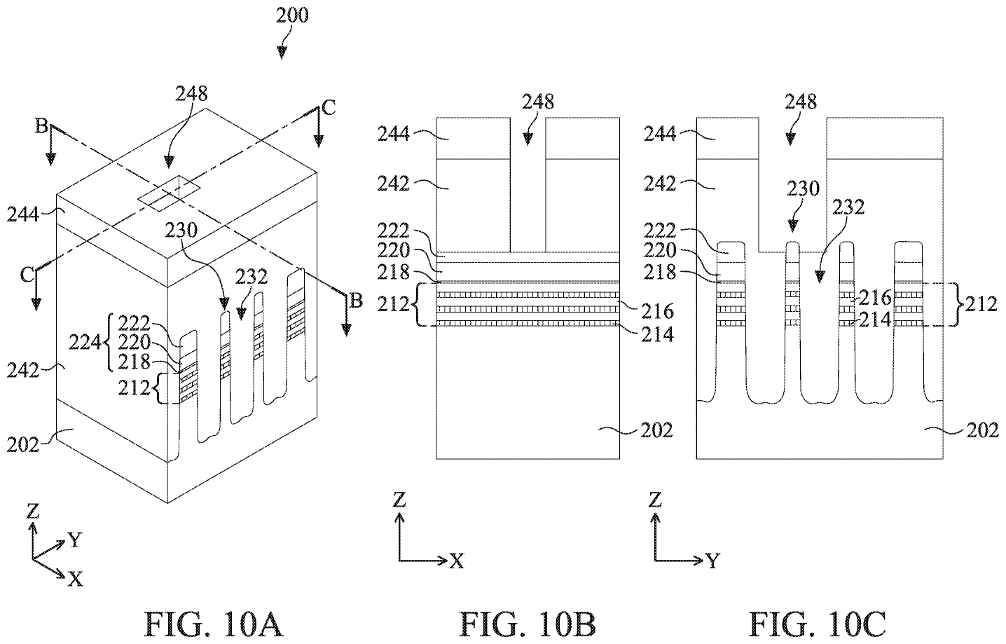

At operation 116, the method 100 (FIG. 2) performs a second etching step (second etching process) of the fin cut process by using the etching system 10, which extends the opening 248 into a top portion of the bottom layer 242, as shown in FIGS. 10A-10C. The photosensitive layer 246 may be consumed during the second etching step. While the device 200 is still in the etching chamber 14, without breaking vacuum (in-situ), the controller 28 may initiate the second etching step by connecting one or more of the etchant suppliers 20 and another one of the carrier gas supply 22 to the etching chamber 14 to introduce a second etching combination of etchants. While the precise etchants utilized are dependent at least in part upon the materials chosen for the bottom layer 242, in an embodiment the second etching combination of etchants may comprise a combination of SO₂ and O₂ along with a diluent such as helium (He). In an embodiment, a pressure in the etching chamber 14 is reduced from the first etching step, such as being set to between about 1 mtorr and about 20 mtorr.

Within the etching chamber 14, the second etching combination of etchants may be ignited into plasma. In an embodiment the second etching combination of etchants may be ignited by the controller 28 sending a signal to the second RF generator 64 to supply to the upper electrode 62 a power of between about 500 W and about 1000 W. In an embodiment, this power is increased from the power applied in the first etching step. Additionally, the transformer-coupled capacitive tuning (TCCT) parameter may be set to between about 2 and about 4. This range for the TCCT parameter in the second etching step is not arbitrary, which safeguards uniformity in extending the opening 248 into the bottom layer 242. In an embodiment, this TCCT parameter is increased from the TCCT parameter applied in the first etching step. The controller 28 may also send a signal to the first RF generator 46 in order to supply an AC voltage to the first electrode 42. In an embodiment the RF generator 46 supplies an AC voltage of between about 50 V and about 300 V.

In an embodiment of the second etching step, the plasma has an ON-and-OFF cycle. Turning plasma on and off once is referred to as one duty cycle, and the second etching step may include many duty cycles. A percentage of ON state in a duty cycle is set between about 5% and about 60%. In OFF state, the power sent to the upper electrode 62 may be reduced to between about 200 W and about 600 W, and the voltage sent to the first electrode 42 may be reduced to between about 0 V to and about 100 V. Once the plasma has been ignited, the process conditions as described above are maintained in order to expose the bottom layer 242 to the plasma generated within the etching chamber 14. In an embodiment the process conditions are maintained and the bottom layer 242 is exposed for a time period of between about 30 seconds and about 130 seconds.

Once the etching process has been performed to a desired length, such as exposing the oxide layer 222 of the fin 230, the controller 28 may stop the flow of the second etching combination of etchants from entering the etching chamber 14, stopping the second etching step. Once the etching process has been stopped, the conditions within the etching chamber 14 may be modified either prior to or during the introduction of a third etching combination of etchants. In the illustrated embodiments as shown in FIG. 10C, the second etching step may intentionally over-etch to expose the tip of the oxide layer 222 of the fin 230, such that about 10% to about 30% of the thickness of the oxide layer 222 protrudes from the bottom of the opening 248.

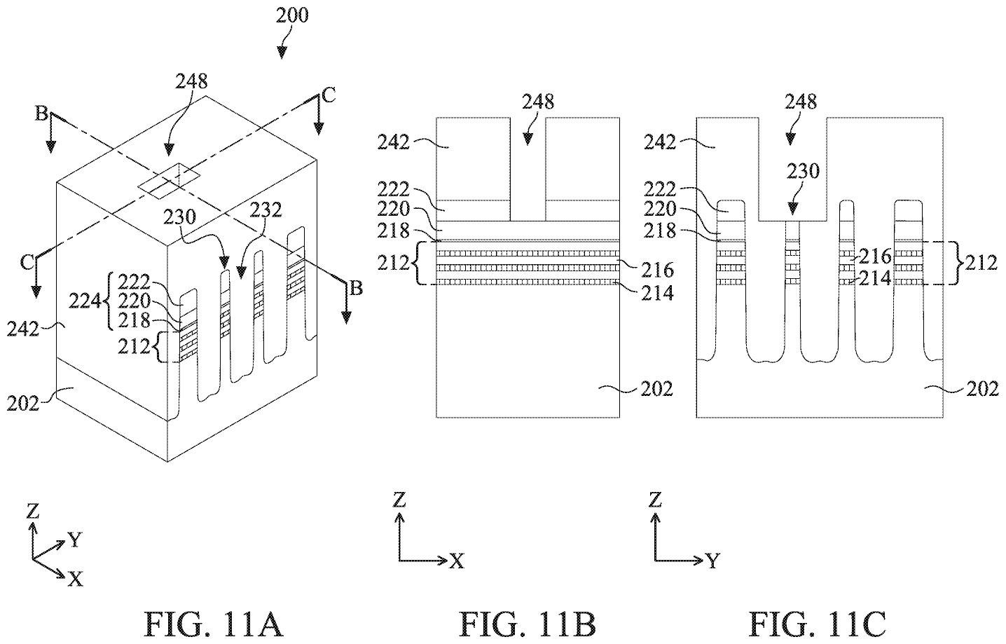

At operation 118, the method 100 (FIG. 2) performs a third etching step (third etching process) of the fin cut process by using the etching system 10, which etches the oxide layer 222 and extends the opening 248 through the oxide layer 222, as shown in FIGS. 11A-11C. The middle layer 244 may be consumed during the third etching step. While the device 200 is still in the etching chamber 14, without breaking vacuum (in-situ), the controller 28 may initiate the third etching step by connecting one or more of the etchant suppliers 20 and another one of the carrier gas supply 22 to the etching chamber 14 to introduce a third etching combination of etchants. While the precise etchants utilized are dependent at least in part upon the materials chosen for the oxide layer 222, in an embodiment the third etching combination of etchants may comprise a combination of SO₂ and CHF₃ along with a diluent such as helium (He). In an embodiment, a pressure in the etching chamber 14 is increased from the pressure applied in the second etching step and back to pressure applied in the first etching step, such as being set to between about 10 mtorr and about 150 mtorr.

Within the etching chamber 14, the third etching combination of etchants may be ignited into plasma. In an embodiment the third etching combination of etchants may be ignited by the controller 28 sending a signal to the second RF generator 64 to supply to the upper electrode 62 a power of between about 300 W and about 1000 W. In an embodiment, this power is reduced from the power applied in the first and second etching steps. Additionally, the transformer-coupled capacitive tuning (TCCT) parameter may be set to between about 2 and about 4. This range for the TCCT parameter in the third etching step is not arbitrary, which safeguards uniformity in extending the opening 248 further into the bottom layer 242. In an embodiment, the TCCT parameter applied in the third etching step remains the same as the TCTT parameter applied in the second etching step. The controller 28 may also send a signal to the first RF generator 46 in order to supply an AC voltage to the first electrode 42. In an embodiment the RF generator 46 supplies an AC voltage of between about 200 V and about 600 V. In an embodiment, this voltage is increased from the voltages applied in the first and second etching steps.

In an embodiment of the first etching step, the plasma is a continuously turned-on plasma. Once the plasma has been ignited, the process conditions as described above are maintained in order to expose the oxide layer 222 to the plasma generated within the etching chamber 14. In an embodiment the process conditions are maintained and the oxide layer 222 is exposed for a time period of between about 10 seconds and about 60 seconds.

Once the etching process has been performed to a desired length, such as exposing the nitride layer 220 of the fin 230, the controller 28 may stop the flow of the third etching combination of etchants from entering the etching chamber 14, stopping the third etching step. Once the etching process has been stopped, the conditions within the etching chamber 14 may be modified either prior to or during the introduction of a fourth etching combination of etchants. In the illustrated embodiments as shown in FIG. 11B, at the conclusion of the third etching step, the oxide layer 222 is etched through.

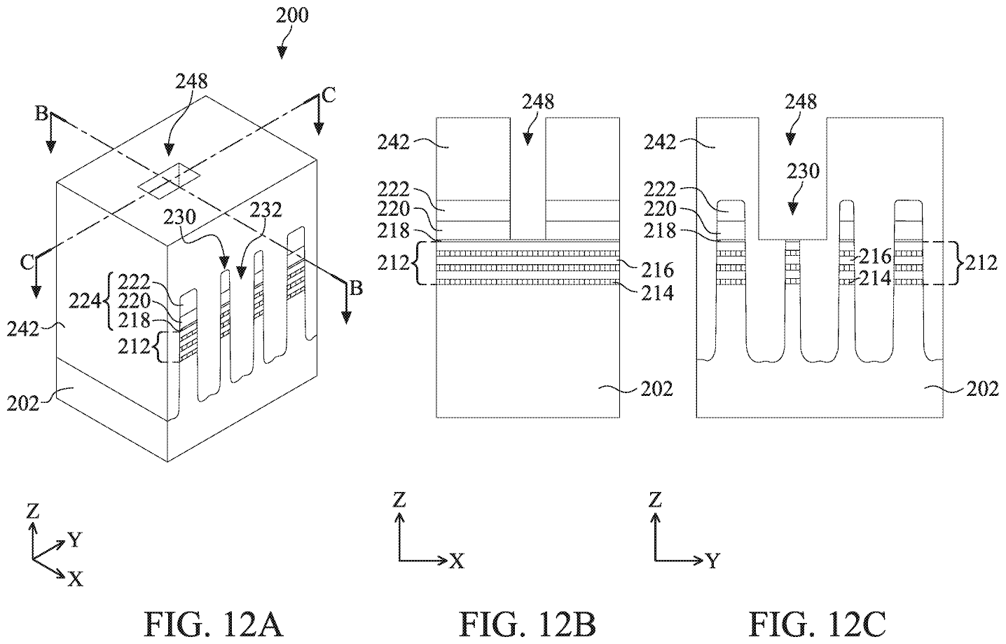

At operation 120, the method 100 (FIG. 2) performs a fourth etching step (fourth etching process) of the fin cut process by using the etching system 10, which etches the nitride layer 220 and extends the opening 248 through the nitride layer 220, as shown in FIGS. 12A-12C. While the device 200 is still in the etching chamber 14, without breaking vacuum (in-situ), the controller 28 may initiate the fourth etching step by connecting one or more of the etchant suppliers 20 and another one of the carrier gas supply 22 to the etching chamber 14 to introduce a fourth etching combination of etchants. While the precise etchants utilized are dependent at least in part upon the materials chosen for the nitride layer 220, in an embodiment the fourth etching combination of etchants may comprise a combination of SO₂ and CHF₃ along with a diluent such as oxygen (O₂). In an embodiment, a pressure in the etching chamber 14 is increased from the third etching step, such as being set to between about 10 mtorr and about 150 mtorr.

Within the etching chamber 14, the fourth etching combination of etchants may be ignited into plasma. In an embodiment the fourth etching combination of etchants may be ignited by the controller 28 sending a signal to the second RF generator 64 to supply to the upper electrode 62 a power of between about 300 W and about 1000 W. This power is increased from the power applied in the third etching step. Additionally, the transformer-coupled capacitive tuning (TCCT) parameter may be set to between about 0 and about 2. This range for the TCCT parameter in the fourth etching step is not arbitrary, which safeguards uniformity in extending the opening 248 further into the bottom layer 242. In an embodiment, the TCCT parameter in the fourth etching step is the lowest in the whole fin cut process. The controller 28 may also send a signal to the first RF generator 46 in order to supply an AC voltage to the first electrode 42. In an embodiment the RF generator 46 supplies an AC voltage of between about 200 V and about 600 V. In an embodiment, this voltage is reduced from the voltages applied in the third etching steps.

In an embodiment of the fourth etching step, the plasma is a continuously turned-on plasma. Once the plasma has been ignited, the process conditions as described above are maintained in order to expose the nitride layer 220 to the plasma generated within the etching chamber 14. In an embodiment the process conditions are maintained and the nitride layer 220 is exposed for a time period of between about 10 seconds and about 60 seconds.

Once the etching process has been performed to a desired length, such as exposing the pad oxide layer 218 of the fin 230, the controller 28 may stop the flow of the fourth etching combination of etchants from entering the etching chamber 14, stopping the fourth etching step. Once the etching process has been stopped, the conditions within the etching chamber 14 may be modified either prior to or during the introduction of a fifth etching combination of etchants. In the illustrated embodiments as shown in FIG. 12B, at the conclusion of the fourth etching step, the nitride layer 220 is etched through.

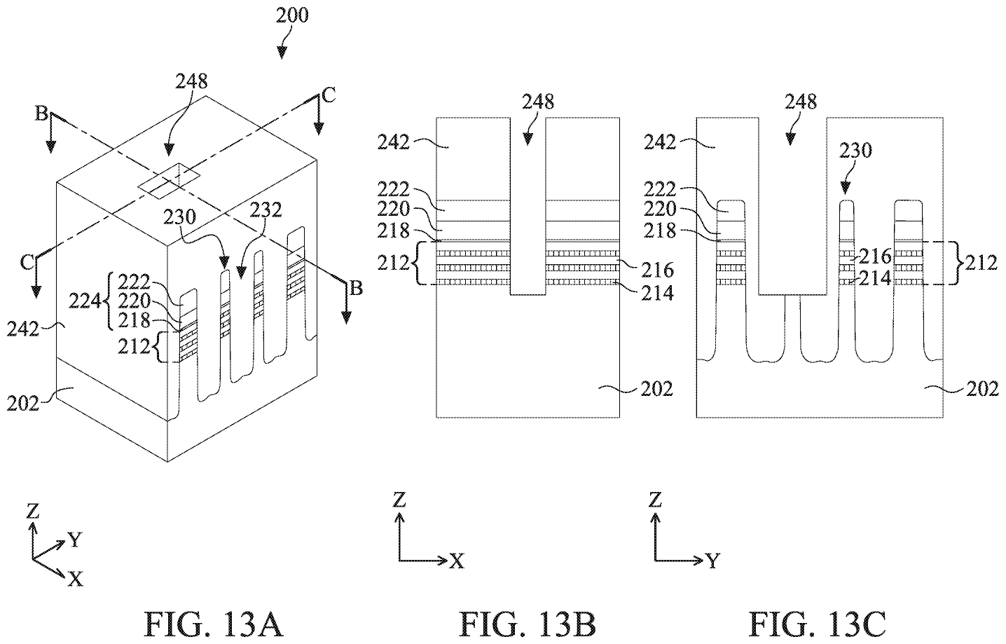

At operation 122, the method 100 (FIG. 2) performs a fifth etching step (fifth etching process) of the fin cut process by using the etching system 10, which etches the epitaxial stack 212 and extends the opening 248 through the epitaxial stack 212, as shown in FIGS. 13A-13C. While the device 200 is still in the etching chamber 14, without breaking vacuum (in-situ), the controller 28 may initiate the fifth etching step by connecting one or more of the etchant suppliers 20 and another one of the carrier gas supply 22 to the etching chamber 14 to introduce a fifth etching combination of etchants. While the precise etchants utilized are dependent at least in part upon the materials chosen for the epitaxial stack 212, in an embodiment the fifth etching combination of etchants may comprise CF₄ along with a diluent such as helium (He). In an embodiment, a pressure in the etching chamber 14 is maintained from the fourth etching step, such as being set to between about 10 mtorr and about 150 mtorr.

Within the etching chamber 14, the fifth etching combination of etchants may be ignited into plasma. In an embodiment the fifth etching combination of etchants may be ignited by the controller 28 sending a signal to the second RF generator 64 to supply to the upper electrode 62 a power of between about 360 W and about 440 W. In an embodiment, this power is reduced from the power applied in the fourth etching step and is the lowest in the whole fin cut process. Additionally, the transformer-coupled capacitive tuning (TCCT) parameter may be set to between about 2 and about 4. This range for the TCCT parameter in the fifth etching step is not arbitrary, which safeguards uniformity in extending the opening 248 further into the bottom layer 242. In an embodiment, the TCCT parameter in the fifth etching step is increased from the TCCT parameter in the fourth etching step and is maintained at the same value as the TCCt parameter in the third etching step. The controller 28 may also send a signal to the first RF generator 46 in order to supply an AC voltage to the first electrode 42. In an embodiment the RF generator 46 supplies an AC voltage of between about 50 V and about 200 V. In an embodiment, this voltage is reduced from the voltages applied in the fourth etching step and is the lowest in the whole fin cut process.

In an embodiment of the fifth etching step, the plasma has an ON-and-OFF cycle. The fifth etching step may include many duty cycles. A percentage of ON state in a duty cycle is set between about 5% and about 80%, which is higher than the percentage of ON state applied in the second etching step. In OFF state, the power sent to the upper electrode 62 may be reduced to between about 80 W and about 120 W, and the voltage sent to the first electrode 42 may be reduced to about 40V to about 60V. Once the plasma has been ignited, the process conditions as described above are maintained in order to expose the epitaxial stack 212 to the plasma generated within the etching chamber 14. In an embodiment the process conditions are maintained and the epitaxial stack 212 is exposed for a time period of between about 10 seconds and about 50 seconds.

Once the etching process has been performed to a desired length, such as exposing the fin base of the fin 230, the controller 28 may stop the flow of the fifth etching combination of etchants from entering the etching chamber 14, stopping the fifth etching step. Once the etching process has been stopped, the conditions within the etching chamber 14 may be modified either prior to or during the introduction of a sixth etching combination of etchants. In the illustrated embodiments as shown in FIG. 13B, at the conclusion of the fifth etching step, the epitaxial stack 212 is etched through.

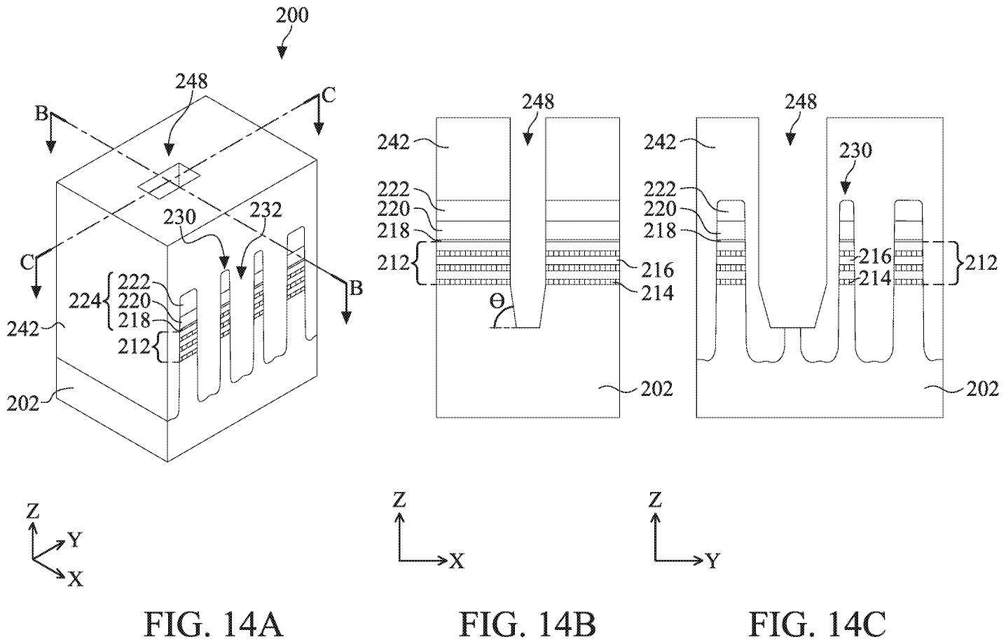

At operation 124, the method 100 (FIG. 2) performs a sixth etching step (sixth etching process) of the fin cut process by using the etching system 10, which etches the fin base and extends the opening 248 further downward, as shown in FIGS. 14A-14C. While the device 200 is still in the etching chamber 14, without breaking vacuum (in-situ), the controller 28 may initiate the sixth etching step by connecting one or more of the etchant suppliers 20 and another one of the carrier gas supply 22 to the etching chamber 14 to introduce a sixth etching combination of etchants. While the precise etchants utilized are dependent at least in part upon the materials chosen for substrate 202, in an embodiment the sixth etching combination of etchants may comprise a combination of CH₂F₂, SF₆, and CH₃F along with a diluent such as helium (He). In an embodiment, a ratio of the CH₂F₂, SF₆, and CH₃F is about 3:8:1. This ratio promotes vertical sidewall profile of the opening 248. In an embodiment, a pressure in the etching chamber 14 is reduced from the fifth etching step, such as being set to between about 4 mtorr and about 8 mtorr.

Within the etching chamber 14, the sixth etching combination of etchants may be ignited into plasma. In an embodiment the sixth etching combination of etchants may be ignited by the controller 28 sending a signal to the second RF generator 64 to supply to the upper electrode 62 a power of between about 400 W and about 500 W. In an embodiment, this power is increased from the power applied in the fifth etching step. Additionally, the transformer-coupled capacitive tuning (TCCT) parameter may be set to between about 2 and about 4. This range for the TCCT parameter in the sixth etching step is not arbitrary, which safeguards uniformity in extending the opening 248 further into the bottom layer 242. In an embodiment, the TCCT parameter in the sixth etching step is maintained the same as the TCCT parameter in the fifth etching step. The controller 28 may also send a signal to the first RF generator 46 in order to supply an AC voltage to the first electrode 42. In an embodiment the RF generator 46 supplies an AC voltage of between about 250 V and about 650 V. In an embodiment, this voltage is increased from the voltage applied in the fifth etching step.

In an embodiment of the sixth etching step, the plasma has an ON-and-OFF cycle. The sixth etching step may include many duty cycles. A percentage of ON state in a duty cycle is set between about 8% and about 15%, which is lower than the percentage of ON state applied in the fifth etching step. In OFF state, the power sent to the upper electrode 62 may be reduced to between about 80 W and about 120 W, and the voltage sent to the first electrode 42 may be reduced to about 40V to about 60V. Once the plasma has been ignited, the process conditions as described above are maintained in order to expose fin base to the plasma generated within the etching chamber 14. In an embodiment the process conditions are maintained and the fin base is exposed for a time period of between about 7 seconds and about 12 seconds.

Once the etching process has been performed to a desired length, such as recessing the fin base to a certain depth, the controller 28 may stop the flow of the sixth etching combination of etchants from entering the etching chamber 14, stopping the sixth etching step. Once the etching process has been stopped, the conditions within the etching chamber 14 may be modified either prior to or during the introduction of a seventh etching combination of etchants. In the illustrated embodiments as shown in FIG. 14B, at the conclusion of the sixth etching step, the lower portion of the opening 248 as under the epitaxial stack 212 may show a tapering sidewall with an angle θ ranging from about 800 to about 88.5° with respect to a top surface of the substrate 202. As a comparison, the upper portion of the opening 248 has a substantially vertical sidewall. The tapering sidewall is mainly due to the etching parameters as set in the sixth etching step promotes the production of polymer byproduct. The polymer byproduct deposits on sidewalls of the opening 248 and slows down the lateral etching rate.

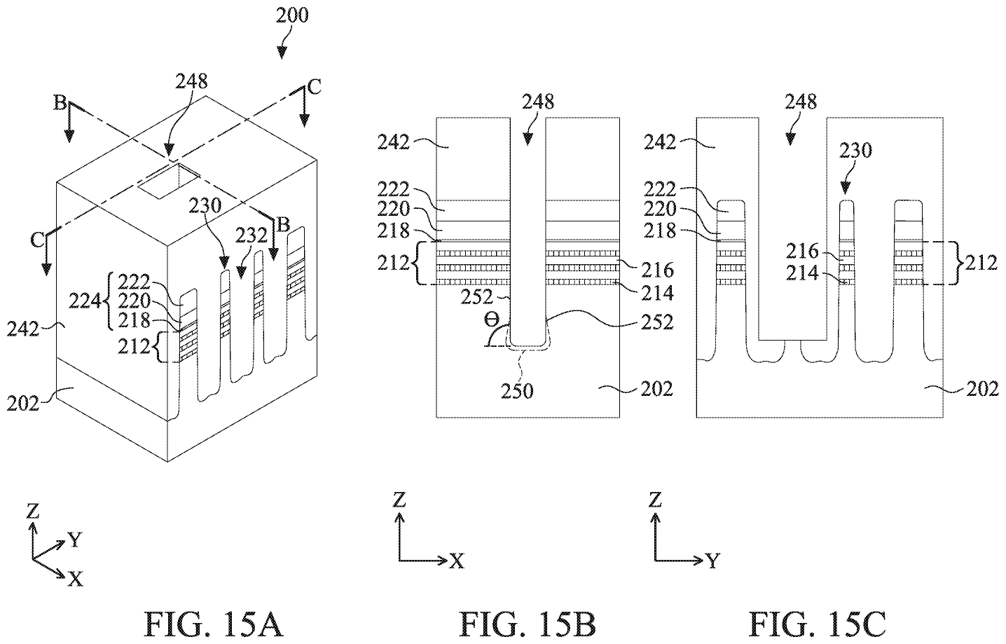

At operation 126, the method 100 (FIG. 2) performs a seventh etching step (seventh etching process) of the fin cut process by using the etching system 10, which further etches the fin base and extends the opening 248 further downward, as shown in FIGS. 15A-15C. While the device 200 is still in the etching chamber 14, without breaking vacuum (in-situ), the controller 28 may initiate the seventh etching step by connecting one or more of the etchant suppliers 20 and another one of the carrier gas supply 22 to the etching chamber 14 to introduce a seventh etching combination of etchants. While the precise etchants utilized are dependent at least in part upon the materials chosen for substrate 202, in an embodiment the seventh etching combination of etchants may comprise a combination of CH₂F₂, SF₆, and CH₃F along with a diluent such as helium (He). In an embodiment, a ratio of the CH₂F₂, SF₆, and CH₃F is about 3:8:1. This ratio promotes vertical sidewall profile of the opening 248. In another embodiment, the concentration of SF₆ is increased about 25% from the sixth etching step, while other etchant concentrations remaining the same, such that a ratio of the CH₂F₂, SF₆, and CH₃F is about 3:10:1. This ratio promotes lateral etching and tilts the sidewall of the opening 248 away from the opening 248. In an embodiment, a pressure in the etching chamber 14 is maintained from the sixth etching step, such as being set to between about 4 mtorr and about 8 mtorr.

Within the etching chamber 14, the seventh etching combination of etchants may be ignited into plasma. In an embodiment the sixth etching combination of etchants may be ignited by the controller 28 sending a signal to the second RF generator 64 to supply to the upper electrode 62 a power of between about 400 W and about 500 W. This power is maintained from the power applied in the sixth etching step. Additionally, the transformer-coupled capacitive tuning (TCCT) parameter may be set to between about 2 and about 4. This range for the TCCT parameter in the seventh etching step is not arbitrary, which safeguards uniformity in extending the opening 248 further into the bottom layer 242. In an embodiment, the TCCT parameter in the seventh etching step is maintained the same as the TCCT parameter in the sixth etching step. The controller 28 may also send a signal to the first RF generator 46 in order to supply an AC voltage to the first electrode 42. In an embodiment the RF generator 46 supplies an AC voltage of between about 450 V and about 550 V. This voltage is increased from the voltage applied in the sixth etching step and may be the highest in the whole fin cut process.

In an embodiment of the seventh etching step, the plasma has an ON-and-OFF cycle. The seventh etching step may include many duty cycles. A percentage of ON state in a duty cycle is set between about 3% and about 7%. In an embodiment, the ON state percentage in the seventh etching step is the whole fin cut process. In OFF state, the power sent to the upper electrode 62 may be reduced to between about 80 W and about 120 W, and the voltage sent to the first electrode 42 may be reduced to about 40V to about 60V. Once the plasma has been ignited, the process conditions as described above are maintained in order to expose fin base to the plasma generated within the etching chamber 14. In an embodiment the process conditions are maintained and the fin base is exposed for a time period of between about 10 seconds and about 60 seconds.

Once the etching process has been performed to a desired length, such as recessing the fin base to a certain depth, the controller 28 may stop the flow of the seventh etching combination of etchants from entering the etching chamber 14, stopping the seventh etching step. In the illustrated embodiments as shown in FIG. 15B, at the conclusion of the seventh etching step, the lower portion of the opening 248 as under the epitaxial stack 212 have a substantially vertical sidewall or even a sidewall that tilts towards the remaining portion of the fin (as represented by the dashed line 250 as an alternative boundary of the opening 248). The sidewall of the opening 248 also constitutes the newly formed fin edge 252. The angle θ between the fin edge 252 and the top surface of the substrate 202 may be not less than about 90°, such as ranging from about 900 to about 93.5°. As a comparison, the upper portion of the opening 248 has a substantially vertical sidewall. The substantially vertical or inwardly tilted fin edge 252 is mainly due to the etching parameters as set in the seventh etching step suppresses the production of polymer byproduct and promotes the lateral etching rate. The lateral etching expands the bottom width of the opening 248 and corrects fin edge 252 to be substantially vertical or even inwardly titled away from the opening 248.

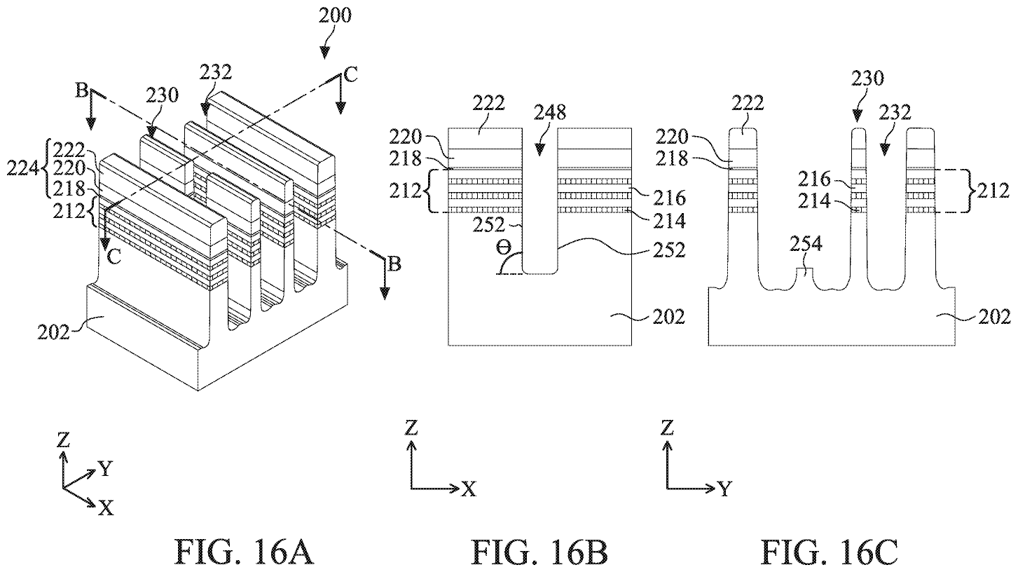

After the seventh etching step, the fin cut process may further perform a cleaning process or a wet-etching process to remove the remaining portion of the bottom layer 242. The resultant structure is shown in FIGS. 16A-16C. The fin cut process “cuts” one of the fins into two segments with opposing fin edges 252. As shown in FIG. 16C, a fin stub 254 may remain as a remnant of the cut fin.

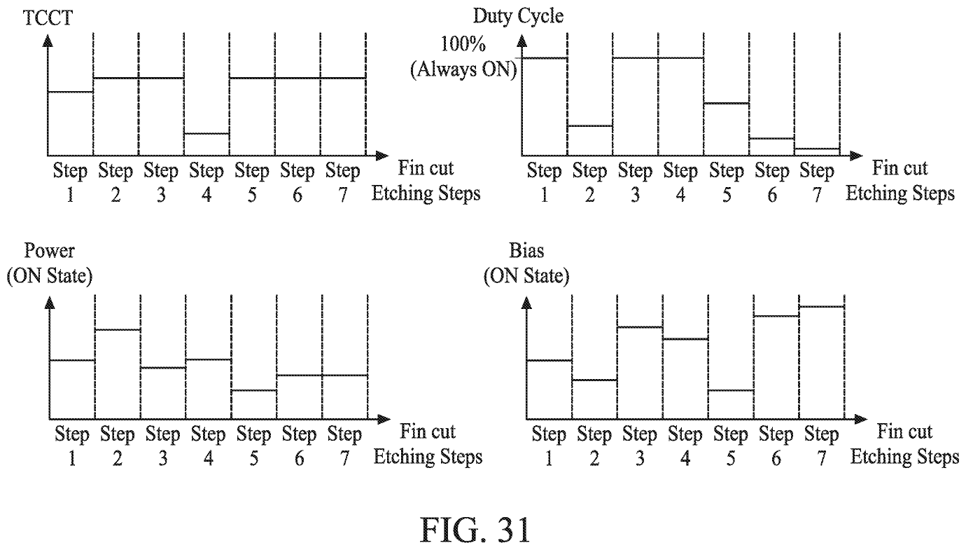

The fin cut process with multiple etching steps tailers the etching parameters to each material layer to be etched. The multiple etching steps safeguard a substantially vertical sidewall of the bottom layer 242, which is subsequently transferred to the underneath layers. The multiple etching steps also safeguard a substantially vertical or even inwardly tilted fin edge. Such fin edge profile allows thicker isolation features to be deposited on the fin edge in later manufacturing processes. The transitions of some etching parameters from first through seventh etching steps, in an embodiment, are illustrated in FIG. 31. Such transitions as illustrated in FIG. 31 are not trivial. This is because such transitions safeguard a substantially vertical or inwardly tilted fin edge, which is beneficial to manufacturing processes to be discussed below.

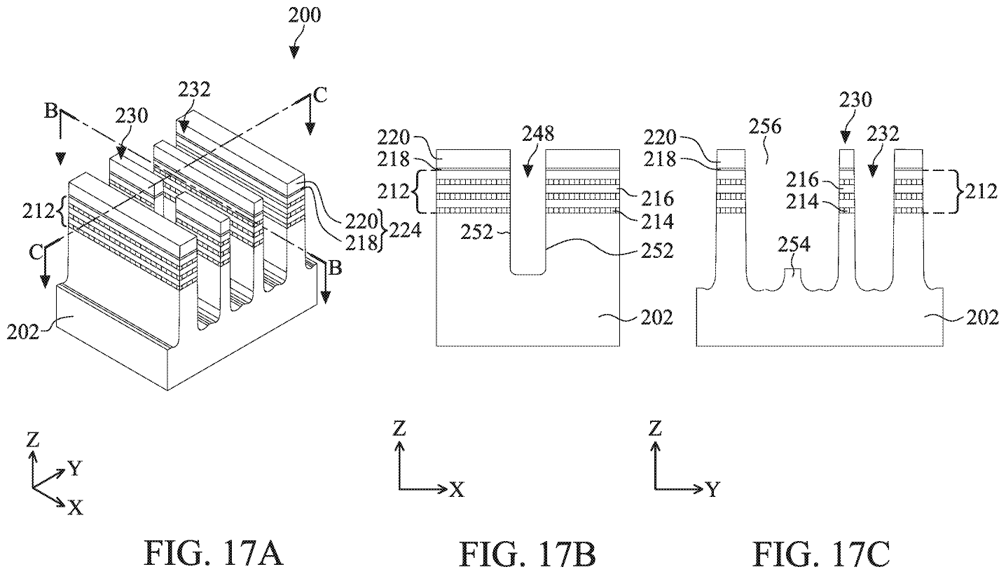

At operation 128, the method 100 (FIG. 2) removes the oxide layer 222 in an etching operation, as shown in FIGS. 17A-17C. In some embodiments, the etching operations are performed using a wet etchant such as, but not limited to, ammonium hydroxide (NH₄OH), tetramethylammonium hydroxide (TMAH), ethylenediamine pyrocatechol (EDP), or potassium hydroxide (KOH) solutions. In other embodiments, the etching operation is performed using a wet etchant such as, but not limited to, HF:HNO₃ solution, HF:CH₃COOH:HNO₃, or H₂SO₄ solution and HF:H₂O₂:CH₃COOH.

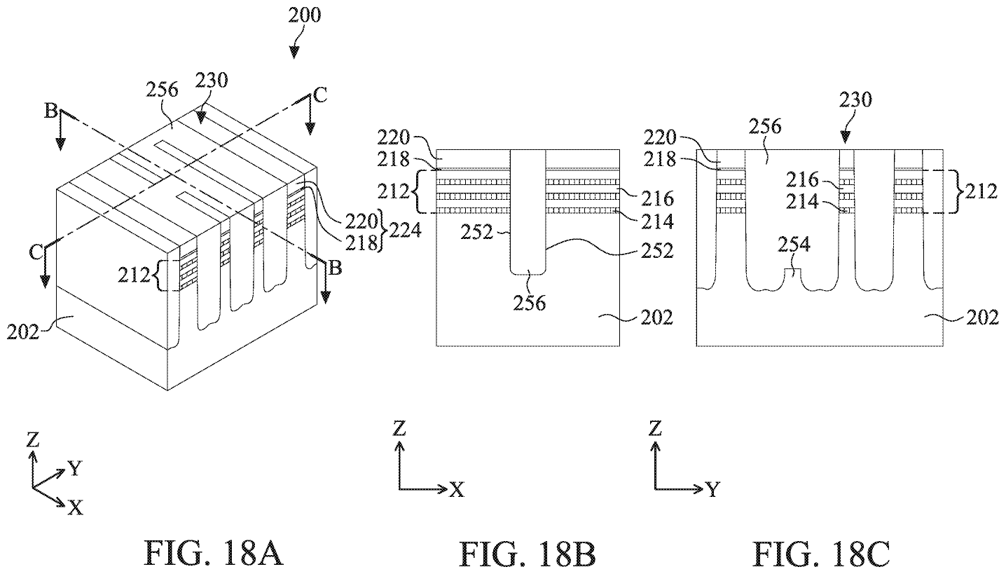

At operation 130, the method 100 (FIG. 2) deposits a dielectric material in the trenches 232 between adjacent fins 230 to form an isolation feature 256, as shown in FIGS. 18A-18C. The isolation feature 256 may include one or more dielectric layers. Suitable dielectric materials for the isolation feature 256 may include silicon oxides, silicon nitrides, silicon carbides, fluorosilicate glass (FSG), low-K dielectric materials, and/or other suitable dielectric materials. The dielectric material may be deposited by any suitable technique including thermal growth, CVD, HDP-CVD, PVD, ALD, and/or spin-on techniques. Then, a planarization operation, such as a CMP process, is performed such that the upper surface of the nitride layer 220 is exposed from the isolation feature 256. In some embodiments, the CMP process further removes the nitride layer 220 and exposes the upper surface of the topmost epitaxial layer 216 of the epitaxial stack 212.

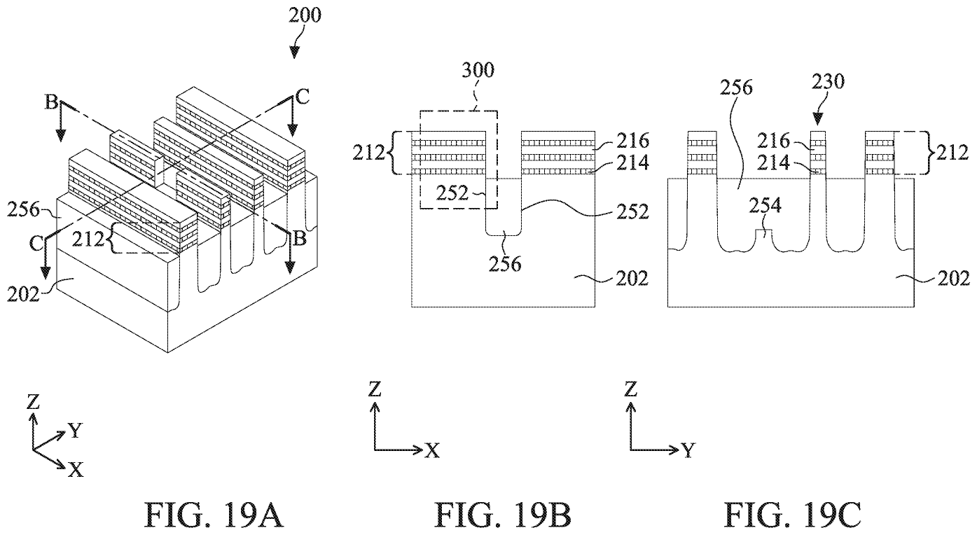

At operation 132, the method 100 (FIG. 2) recesses the isolation feature 256 to form shallow trench isolation (STI) features (thus also denoted as STI features 256), as shown in FIGS. 19A-19C. Any suitable etching technique may be used to recess the isolation features 256 including dry etching, wet etching, RIE, and/or other etching methods, and in an exemplary embodiment, an anisotropic dry etching is used to selectively remove the dielectric material of the isolation features 256 without etching the fins 230. In some embodiments, the hard mask layer 224 is removed by a CMP process performed prior to the recessing of the isolation features 256. In some embodiments, the hard mask layer 224 is removed by an etchant used to recess the isolation features 256. In the illustrated embodiment as shown in FIG. 18B, the top surface of the STI features 256 may be below the bottom surface of the epitaxial stack 212. Alternatively, the top surface of the STI features 256 may be coplanar with the bottom surface of the epitaxial stack 212, in accordance with some other embodiments.

A region 300 in the FIG. 18B, which includes the fin edge 252 formed by the fin cut process and the STI feature 256 deposited on the fin edge 252, through following operations of the method 100 is further illustrated in FIGS. 20-30.

At operation 134, the method 100 (FIG. 2) conformally deposits an oxide layer 260 on the top and sidewall surfaces of the epitaxial stack 212 and the top surface of the STI feature 256, as shown in FIG. 20. In some embodiments, the oxide layer 260 is thermal oxide formed by a thermal oxidation process conducted in oxygen ambient. In some embodiments, the oxide layer 260 is formed by CVD, PVD, ALD, or other suitable techniques. A portion of the fin edge 252 under the epitaxial stack 212 and above the STI feature 256 is in physical contact with the oxide layer 260. Also depicted in FIG. 20, the fin edge 252 includes a top sidewall (including sidewall of the epitaxial stack 212) that is substantially vertical and a bottom sidewall that inwardly tilted with an angle θ larger than 900 with respect to a top surface of the substrate 202. Thus, a bottom portion of the STI feature 256 is wider than its top portion. The bottom portion of the fin edge 252 is tilted as corresponding to the seventh etching step of the fin cut process discussed above.

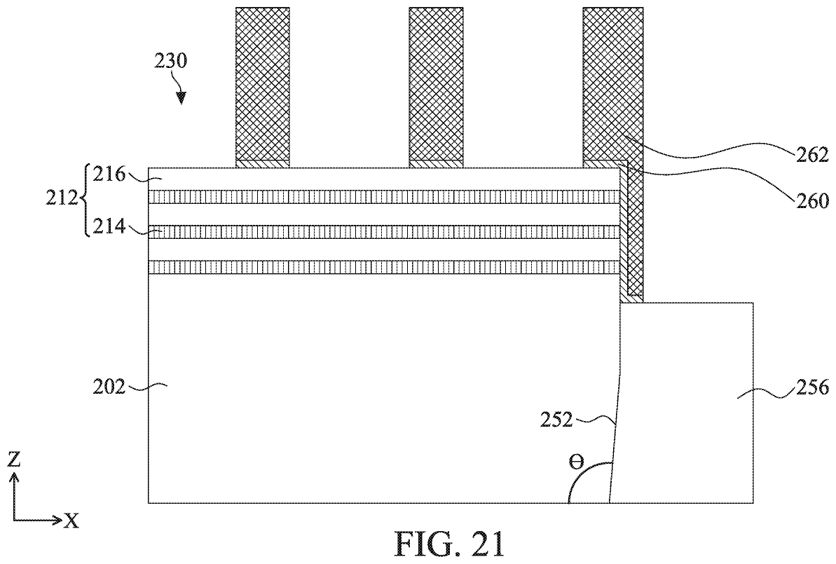

At operation 136, the method 100 (FIG. 2) forms sacrificial (dummy) gate structures 262, as shown in FIG. 21. In the illustrated embodiment, two (2) sacrificial gate structures 262 are formed on the top surface of the fin 230 and one (1) sacrificial gate structure is formed on the edge of the fin 230, but the number of the sacrificial gate structures 262 is not limited to one, two, or more sacrificial gate structures, which are arranged in the X-direction. The two sacrificial gate structures 262 are formed over portions of the fin 230 which are to be channel regions of the to-be-formed GAA transistors. The one sacrificial gate structure 262 deposited on the edge of the fin 230 covers the sidewalls of the epitaxial stack 212 and lands on the top surface of the STI feature 256. The sacrificial gate structures 262 may include polycrystalline silicon or amorphous silicon. A layer of polycrystalline silicon or amorphous silicon may be deposited using CVD, PVD, ALD, or other suitable process, and patterned into the sacrificial gate structures 262. The patterning process also removes portions of the oxide layer 260 not covered by the sacrificial gate structures 262. By patterning the sacrificial gate structures 262, the fin 230 are partially exposed on opposite sides of the sacrificial gate structures 262, thereby defining source/drain (S/D) regions.

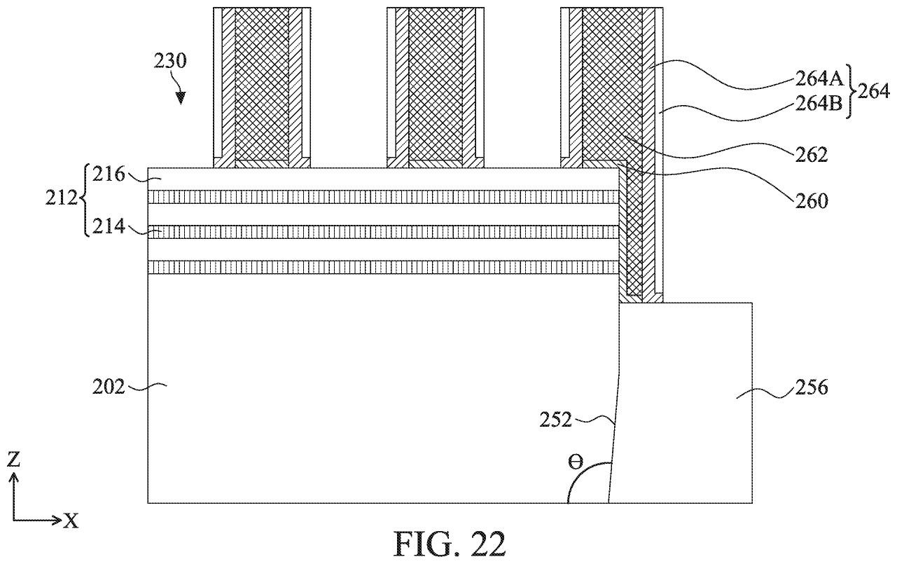

At operation 138, the method 100 (FIG. 2) forms gate spacers 264 on sidewalls of the sacrificial gate structures 262, as shown in FIG. 22. The gate spacers 264 may include a dielectric material such as silicon oxide, silicon nitride, silicon carbide, silicon oxynitride, SiCN films, silicon oxycarbide, SiOCN films, and/or combinations thereof. In some embodiments, the gate spacers 264 include multiple layers, such as a first gate spacer layer 264A and a second gate spacer layer 264B. By way of example, the gate spacers 234 may be formed by blanket depositing a dielectric material layer in a conformal manner over the sacrificial gate structures 262 using processes such as, a CVD process, a subatmospheric CVD (SACVD) process, a flowable CVD process, an ALD process, a PVD process, or other suitable process. In the illustrated embodiment, the deposition of the dielectric material layer is followed by an etching-back (e.g., anisotropically) process to remove the dielectric material layer from horizontal surfaces and expose the top surface of the sacrificial gate structures 262 and the top surface of the fins 230 adjacent to but not covered by the sacrificial gate structures 262 (e.g., S/D regions). The dielectric material layer may remain on the sidewalls of the sacrificial gate structures 262 as the gate spacers 264 (and/or on the sidewalls of the fins 230 as the fin spacers). Outside the fin edge 252, the first gate spacer layer 264A and the second gate spacer layer 264B extend below the epitaxial stack 212 and land on the STI feature 256.

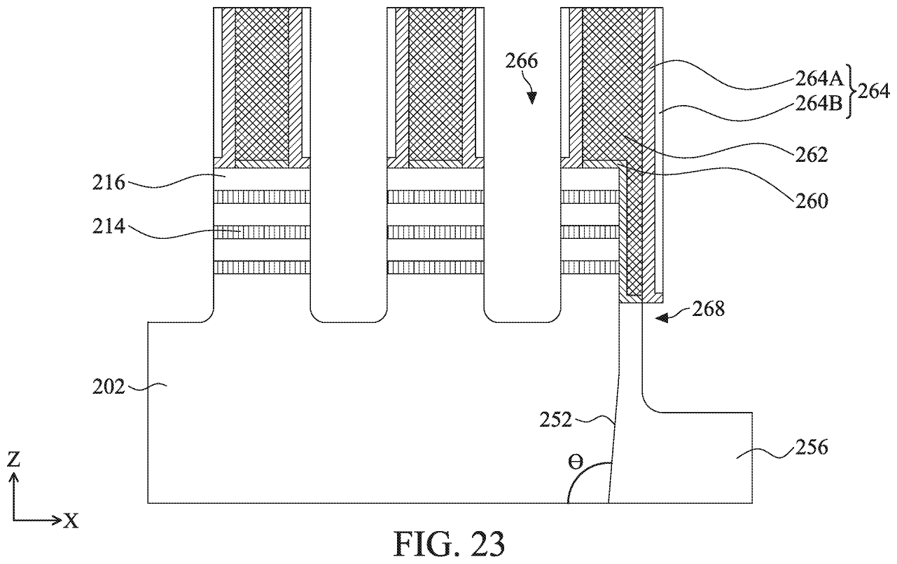

At operation 140, the method 100 (FIG. 2) recesses portions of the fin 230 to form S/D trenches (or S/D recesses) 266 in the S/D regions, as shown in FIG. 23. The stacked epitaxial layers 214 and 216 are etched down at the S/D regions. In many embodiments, operation 140 forms the S/D trenches 266 by a suitable etching process, such as a dry etching process, a wet etching process, or an RIE process. The etching process at operation 140 may implement a dry etching process using an etchant including a bromine-containing gas (e.g., HBr and/or CHBR₃), a fluorine-containing gas (e.g., CF₄, SF₆, CH₂F₂, CHF₃, and/or C₂F₆), other suitable gases, or combinations thereof. The etching process may also recess a top portion of the STI feature 256 in forming a recess 268 under the gate spacer 264 outside the fin edge 252 due to the limited etching contrast towards the STI feature 256.

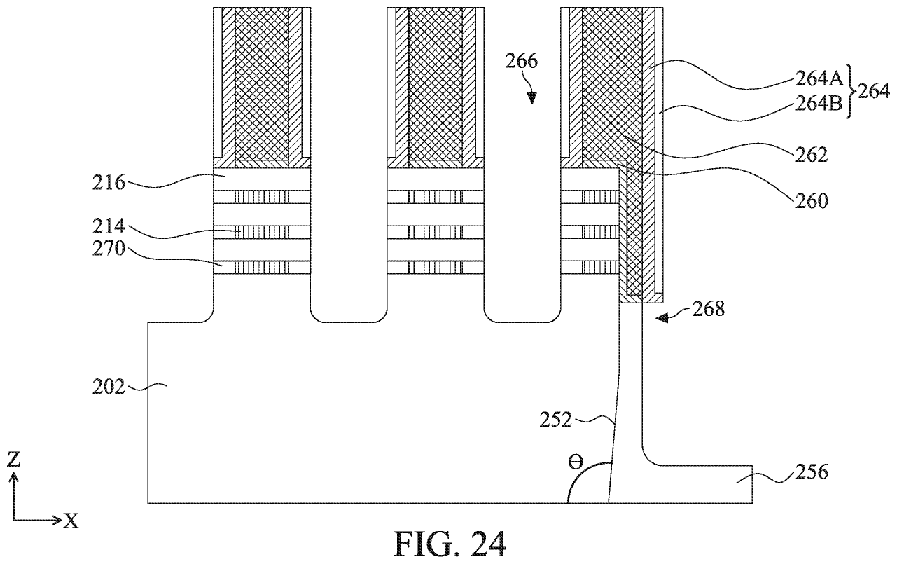

At operation 142, the method 100 (FIG. 2) forms inner spacers 270 abutting end portions of the epitaxial layers 214, as shown in FIG. 24. Operation 142 may first laterally etch the end portions of the epitaxial layers 214, thereby forming cavities to be filled by a dielectric material as the inner spacers 270. The epitaxial layers 214 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. Alternatively, operation 142 may first selectively oxidize lateral ends of the epitaxial layers 214 that are exposed in the S/D trenches 266 to increase the etch selectivity between the epitaxial layers 214 and 216. In some examples, the oxidation process may be performed by exposing the device 200 to a wet oxidation process, a dry oxidation process, or a combination thereof. Next, operation 142 forms inner spacers 270 on the recessed lateral ends of the upper epitaxial layers 214. By way of example, operation 142 may include blanket depositing an inner spacer material layer in the S/D trenches 266. Particularly, the inner spacer material layer is deposited on the recessed lateral ends of the upper epitaxial layers 214 exposed in the cavities and on the sidewalls of the epitaxial layers 216 exposed in the S/D trenches 266. The inner spacer material layer may include silicon oxides, silicon nitrides, silicon carbides, silicon carbide nitride, silicon oxide carbide, silicon carbide oxynitride, and/or other suitable dielectric materials. In some embodiments, the inner spacer material layer is deposited as a conformal layer with substantially uniform thickness on different surfaces. The inner spacer material layer can be formed by ALD or any other suitable method. By conformally forming the inner spacer material layer, a volume of the cavities is reduced or completely filled. After the inner spacer material layer is deposited, an etching operation is performed to partially remove the inner spacer material layer from the S/D trenches 236. Particularly, the inner spacer material layer is removed from the sidewalls of the epitaxial layers 216. By this etching, the inner spacer material layer remains substantially within the cavities, because of a small volume of the cavities. Generally, plasma dry etching etches a layer in wide and flat areas faster than a layer in concave (e.g., holes, grooves and/or slits) portions. Thus, the inner spacer material layer can remain inside the cavities. The remaining portions of the inner spacer material layer inside the cavities provides isolation between to-be-formed metal gate structures and to-be-formed S/D epitaxial features, which are referred to as the inner spacers 270. The etching process may further recess a top portion of the STI feature 256 in enlarging the recess 268 under the gate spacer 264 outside the fin edge 252 due to the limited etching contrast between the dielectric materials of the inner spacers 270 and the STI feature 256.

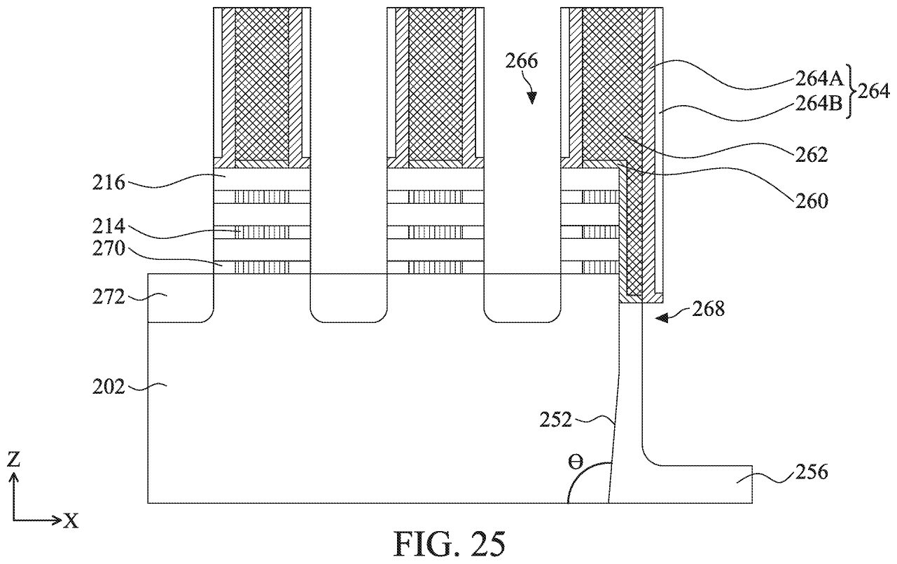

At operation 144, the method 100 (FIG. 2) forms a semiconductor layer 272 in the S/D trenches 266, as shown in FIG. 25. The semiconductor layer 272 may be deposited using an epitaxial growth process or by other suitable processes. In some embodiments, epitaxial growth of semiconductor layers 272 is achieved by a molecular beam epitaxy (MBE) process, a chemical vapor deposition (CVD) process, a metalorganic chemical vapor deposition (MOCVD) process, other suitable epitaxial growth process, or combinations thereof. In some embodiments, the semiconductor layer 272 includes silicon. In furtherance of some embodiments, the semiconductor layer 272 is a bulk crystalline silicon free of dopants. A top surface of the semiconductor layer 272 may be below a top surface of the bottommost inner spacer 270.

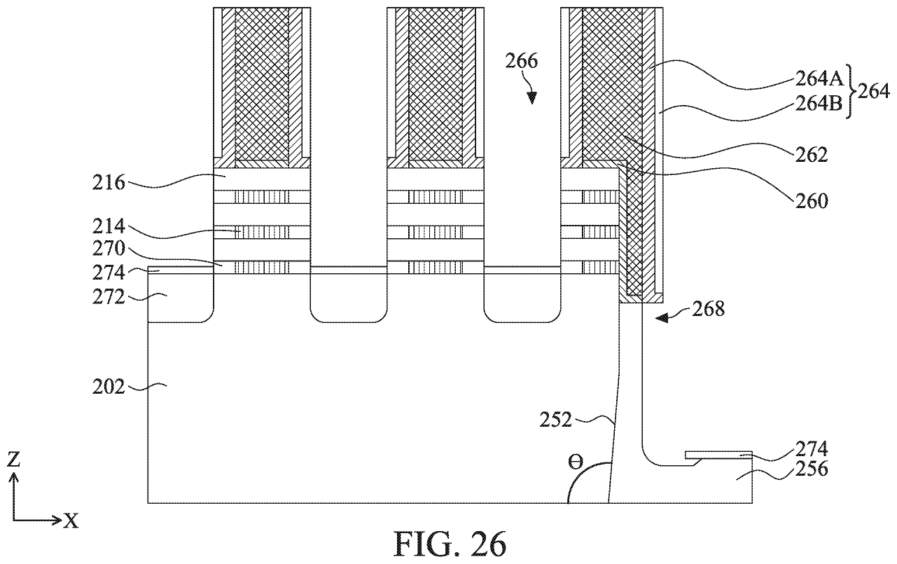

At operation 146, the method 100 (FIG. 2) forms a capping layer 274 covering at least the top surface of the semiconductor layer 272, as shown in FIG. 26. The capping layer 274 may include silicon oxide (SiO₂), aluminum oxide (AlO), silicon nitride (SiN), silicon oxynitride (SiON), silicon carbonitride (SiCN), or silicon carbon oxynitride (SiCON). The capping layer 274 may include the same or different dielectric material compositions with the inner spacers 270, in accordance with some embodiments. The capping layer 274 separates the semiconductor layer 272 from the subsequently formed epitaxial features, thus suppress the substate leakage from the epitaxial features into the semiconductor layer 272. In the illustrated embodiment, the top surface of the capping layer 274 is substantially level with the bottom surface of the bottommost epitaxial layer 216. Alternatively, the top surface of the capping layer 274 may be above or below the bottom surface of the bottommost epitaxial layer 216. In various embodiments, the top surface of the capping layer 274 is below the top surface of the bottommost epitaxial layer 216. In some embodiments, the capping layer 274 is first conformally deposited in the S/D trenches 266 using CVD, PVD, ALD, or other suitable process, covering the top surface of the semiconductor layer 272 and over the sidewalls of the S/D trenches 266. The capping layer 274 is also conformally deposited on exposed surfaces of the STI feature 256. Subsequently, an etching-back process is performed to remove portions of the capping layer 274 from the sidewalls of the S/D trenches 266, while other portions of the capping layer 274 covering the top surface of the semiconductor layer 272 remain, including on the STI feature 256 that is offset from the gate spacer 264 outside the fin edge 252. Any suitable etching technique may be used to partially remove the capping layer 274 from the S/D trenches 266 including dry etching, wet etching, RIE, and/or other etching methods, and in an exemplary embodiment, an anisotropic dry etching is used. The etching-back process may further recess the STI feature 256 and extend the recess 268 under the capping layer 274 due to the limited etching contrast between the dielectric materials of the capping layer 274 and the STI feature 256.

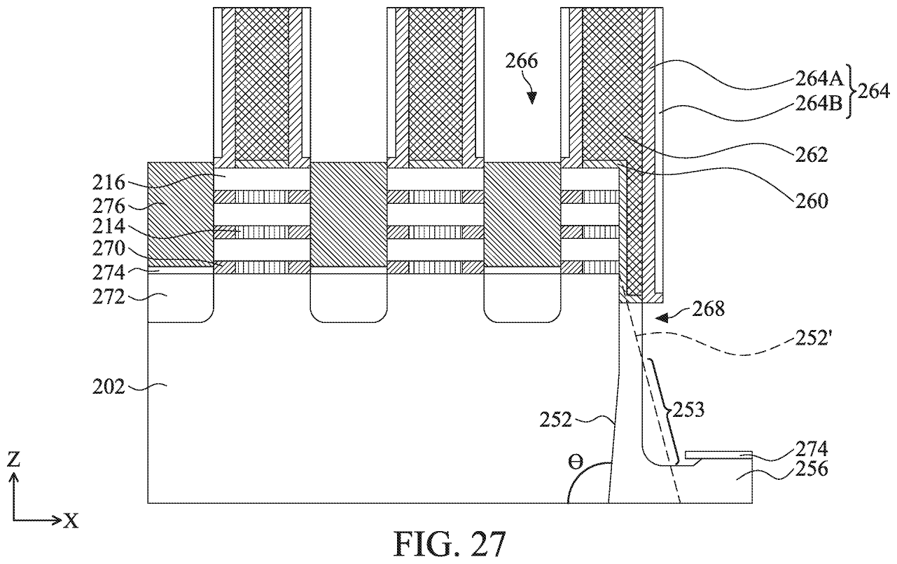

At operation 148, the method 100 (FIG. 2) forms S/D epitaxial features 276 in the S/D trenches 266, as shown in FIG. 27. In some embodiments, the S/D epitaxial features 276 include epitaxially grown semiconductor materials such as epitaxially grown silicon, germanium, or silicon germanium. The S/D epitaxial features 276 can be formed by any epitaxy processes including chemical vapor deposition (CVD) techniques (for example, vapor phase epitaxy and/or Ultra-High Vacuum CVD), molecular beam epitaxy, other suitable epitaxial growth processes, or combinations thereof. The S/D epitaxial features 276 may be doped with n-type dopants and/or p-type dopants. In some embodiments, for n-type transistors, the S/D epitaxial features 276 include silicon and can be doped with carbon, phosphorous, arsenic, other n-type dopant, or combinations thereof (for example, forming Si:C S/D epitaxial features, Si:P S/D epitaxial features, or Si:C:P S/D epitaxial features). In some embodiments, for p-type transistors, the S/D epitaxial features 276 include silicon germanium or germanium, and can be doped with boron, other p-type dopant, or combinations thereof (for example, forming Si:Ge:B S/D epitaxial features). The S/D epitaxial features 276 may include multiple epitaxial semiconductor layers having different levels of dopant density. In some embodiments, annealing processes (e.g., rapid thermal annealing (RTA) and/or laser annealing) are performed to activate dopants in the S/D epitaxial features 276. The bottom surface of the S/D epitaxial features 276 fully rests on the top surface of the capping layer 274.

Still referring to FIG. 27, if the fin edge 252 is not substantially vertical or inwardly tilted as depicted, but outwardly tapering as represented by the dashed line 252′, a bottom portion of the dash line 252′ (denoted as part 253) may extend outside of the gate spacer 264. Thus, even the STI feature 256 is initially deposited on the fin edge 252, the bottom portion of the STI feature 256 on the part 253 is lack of etch protection from the gate spacer 264 and likely suffering etch lost. If the bottom portion of the STI feature 256 is etched away, the fin edge 252 would be exposed, and in turn the epitaxial feature 276 would also grow form the fin edge 252. The epitaxial feature 276 laterally protruding from the fin edge 252 may cause the fin edge 252 to circuit short with nearby conductive features and cause device malfunction. The fin cut process discussed above safeguards a vertical or inwardly tilted fin edge and ensures a layer of the STI feature 256 under the gate spacer 264 would remain on the fin edge, which avoids the circuit short.

At operation 150, the method 100 (FIG. 2) forms a contact etch stop layer (CESL) 278 over the S/D epitaxial features 276 and an interlayer dielectric (ILD) layer 280 over the CESL layer 278, as shown in FIG. 26. The CESL layer 278 may include silicon nitride, silicon oxynitride, silicon nitride with oxygen (O) or carbon (C) elements, and/or other materials; and may be formed by CVD, PVD (physical vapor deposition), ALD, or other suitable methods. The ILD layer 280 may include tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 280 may be formed by PECVD or FCVD (flowable CVD), or other suitable methods. In some embodiments, forming the ILD layer 280 further includes performing a CMP process to planarize a top surface of the device 200. As discussed above, a portion of the capping layer 274 may remain on the STI feature 256, and the CESL 278 physically contacts this portion of the capping layer 274. Further, a portion of the recess 268 directly under the capping layer 274 may be sealed by the CESL 278 and denoted as a void or cavity 268.

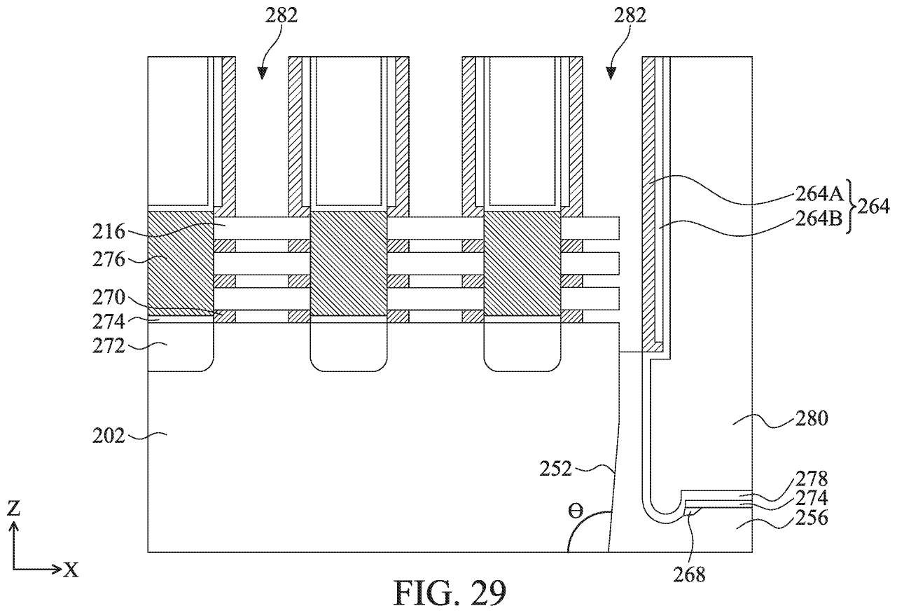

At operation 152, the method 100 (FIG. 2) removes the sacrificial gate structures 262 and the underneath oxide layer 260 to form gate trenches 282 in an etch process, such as plasma dry etching and/or wet etching. The gate trenches 282 expose the epitaxial layers 214 and 216 in channel regions. The operation 124 then releases channel structures from channel regions. The resultant structure at the conclusion of operation 152 is shown in FIG. 29. In the illustrated embodiment, channel layers are the epitaxial layers 216 in the form of nanostructures (e.g., nanosheets or nanowires). In the present embodiment, the epitaxial layers 216 include silicon, and the epitaxial layers 214 include silicon germanium. The epitaxial layers 214 are selectively removed. In some implementations, the selectively removal process includes oxidizing the epitaxial layers 214 using a suitable oxidizer, such as ozone. Thereafter, the oxidized epitaxial layers 214 may be selectively removed from the gate trenches 282. To further this embodiment, operation 124 includes a dry etching process to selectively remove the epitaxial layers 214, for example, by applying an HCl gas at a temperature of about 500° C. to about 700° C., or applying a gas mixture of CF₄, SF₆, and CHF₃. For the sake of simplicity and clarity, after the channel structure release, the epitaxial layers 216 are denoted as the channel layers 216.

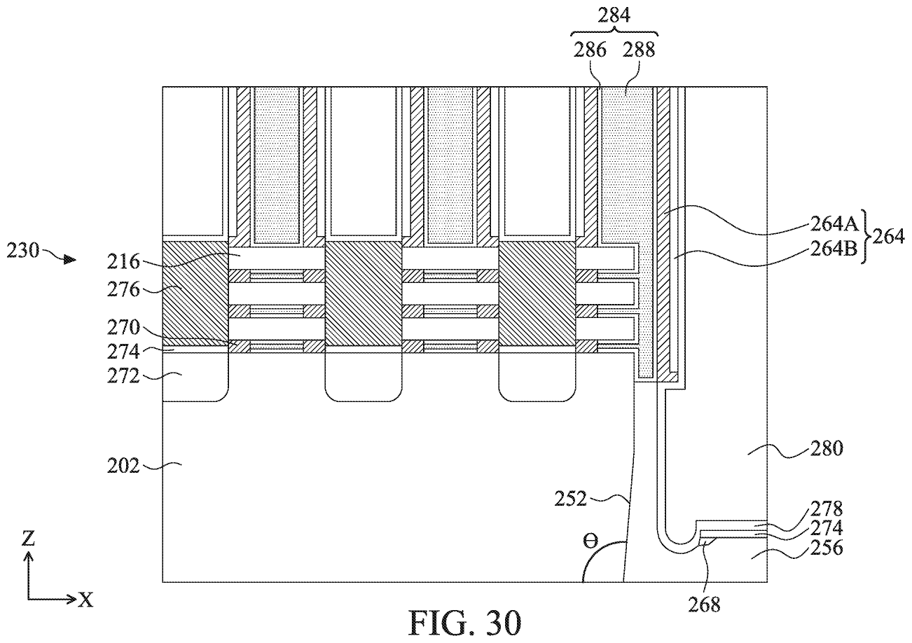

At operation 154, the method 100 (FIG. 2) forms metal gate structures 284 in the gate trenches 282, as shown in FIG. 30. The metal gate structures 284 wrap around each of the channel layers 216 in the channel regions. The inner spacers 270 separate the metal gate structures 284 from contacting the S/D epitaxial features 276. The bottommost inner spacer 270 also separates the metal gate structures 284 from contacting the semiconductor layer 272 and the capping layer 274.

The metal gate structures 284 include a gate dielectric layer 286 wrapping each channel structures 216 in the channel regions and a gate electrode layer 288 formed on the gate dielectric layer 286. In some embodiments, the gate dielectric layer 286 includes one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂-Al₂O₃) alloy, other suitable high-k dielectric materials, and/or combinations thereof. In some embodiments, the gate dielectric layer 286 includes an interfacial layer formed between the channel structures and the high-k dielectric material. The gate dielectric layer 286 may be formed by CVD, ALD or any suitable method. In one embodiment, the gate dielectric layer 286 is formed using a highly conformal deposition process such as ALD in order to ensure the formation of a gate dielectric layer having a uniform thickness around each channel layers. The gate electrode layer 288 is formed on the gate dielectric layer 286 to surround each channel structure 216. The gate electrode layer 288 includes one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. The gate electrode layer 288 may be formed by CVD, ALD, electro-plating, or other suitable method. In certain embodiments of the present disclosure, one or more work function adjustment layers are interposed between the gate dielectric layer and the gate electrode layer. The work function adjustment layers are made of a conductive material such as a single layer of TiN, TaN, TaAlC, TiC, TaC, Co, Al, TiAl, HfTi, TiSi, TaSi or TiAlC, or a multilayer of two or more of these materials. For the n-channel FET, one or more of TaN, TaAlC, TiN, TiC, Co, TiAl, HfTi, TiSi and TaSi is used as the work function adjustment layer, and for the p-channel FET, one or more of TiAlC, Al, TiAl, TaN, TaAlC, TiN, TiC and Co is used as the work function adjustment layer. The work function adjustment layer may be formed by ALD, PVD, CVD, e-beam evaporation, or other suitable process. Further, the work function adjustment layer may be formed separately for the n-type transistors and the p-type transistors which may use different metal layers.

At operation 156, the method 100 (FIG. 2) performs further fabrication processes to the device 200. For example, it may form one or more interconnect layers on the device 200, perform other back-end-of-line (BEOL) processes, and form passivation layers on the device 200.

Although not intended to be limiting, embodiments of the present disclosure provide one or more of the following advantages. For example, embodiments of the present disclosure perform a fin cut process including multiple etching steps, which warrants a substantially vertical or inwardly tilted fin edge. Such fin edge profile advantageously safeguards the fin edge against being exposed due to isolation features' etch loss. Embodiments of the present disclosure can be readily integrated into existing semiconductor manufacturing processes.

In one exemplary aspect, the present disclosure is directed to a method. The method includes forming a fin protruding from a substrate, the fin including an epitaxial stack over a fin base and a hard mask layer over the epitaxial stack, the epitaxial stack including first and second semiconductor layers of different material compositions, performing a first etching process to etch the hard mask layer, the first etching process including applying a first combination of etchants, performing a second etching process to etch the epitaxial stack, the second etching process including applying a second combination of etchants, and performing a third etching process to etch the fin base, the third etching process including applying a third combination of etchants. The first, second, and third combinations of etchants are different from each other. In some embodiments, the first combination of etchants includes CHF₃ and SO₂, the second combination of etchants includes CF₄, and the third combination of etchants includes CH₂F₂, SF₆, and CH₃F. In some embodiments, the first etching process includes applying a first transformer-coupled capacitive tuning (TCCT) parameter, the second etching process includes applying a second TCCT parameter, the third etching process includes applying a third TCCT parameter, and the first TCCT parameter is different from the second and third TCCT parameters. In some embodiments, the second and third TCC parameters have a same value. In some embodiments, the first TCCT parameter is smaller than the second and third TCCT parameters. In some embodiments, the first TCCT parameter is in a range between 0 and 2, and the second and third TCCT parameters are in a range between 2 and 4. In some embodiments, the hard mask layer includes a nitride layer and an oxide layer over the nitride layer, the first etching process includes a first etching step to etch the oxide layer with a first transformer-coupled capacitive tuning (TCCT) parameter and a second etching step to etch the nitride layer with a second TCCT parameter, and the first TCCT parameter is larger than the second TCCT parameter. In some embodiments, the first etching step includes applying the first combination of etchants, the second etching step includes applying a fourth combination of etchants, and the first combination of etchants is different from the fourth combination of etchants. In some embodiments, the third etching process includes a first etching step and a second etching step following the first etching step, the first etching step includes a first lateral etching rate, the second etching step includes a second lateral etching rate, and the first lateral etching rate is smaller than the second lateral etching rate. In some embodiments, the second etching step increases a concentration of one etchant in the third combination of etchants compared to the first etching step.

In another exemplary aspect, the present disclosure is directed to a method. The method includes forming a fin protruding from a substrate, the fin including a dielectric portion over a semiconductor portion, forming a bottom resist layer over the dielectric portion of the fin, forming a middle resist layer over the bottom resist layer, performing a first plasma etching process to etch the middle resist layer with a first set of plasma etching parameters, performing a second plasma etching process to etch the bottom resist layer with a second set of plasma etching parameters, and performing a third plasma etching process to etch the fin with a third set of plasma etching parameters. The first, second, and third sets of plasma etching parameters are different from each other. In some embodiments, the first plasma etching parameters includes a first transformer-coupled capacitive tuning (TCCT) parameter, the second plasma etching parameters includes a second TCCT parameter, the third plasma etching parameters includes a third TCCT parameter, and the first TCCT parameter is different from the second TCCT parameter and different from the third TCCT parameter. In some embodiments, the second TCCT parameter equals the third TCCT parameter. In some embodiments, the second TCCT parameter is different from the third TCCT parameter. In some embodiments, the third plasma etching process includes a first plasma etching step to etch the dielectric portion of the fin with the third set of plasma etching parameters, the third plasma etching process includes a second plasma etching step to etch the semiconductor portion of the fin with a fourth set of plasma etching parameters, and the third set of plasma etching parameters is different from the fourth set of plasma etching parameters. In some embodiments, the second plasma etching step includes etching the semiconductor portion of the fin with a first lateral etching rate and etching the semiconductor portion of the fin with a second lateral etching rate that is larger than the first lateral etching rate. In some embodiments, the performing of the third plasma etching process creates an edge of the fin, and the edge of the fin from top to bottom tilts inwardly towards the fin.

In another exemplary aspect, the present disclosure is directed to a semiconductor device. The semiconductor device includes a fin base protruding from a substate, a plurality of nanostructures vertically suspended above the fin base, a gate structure wrapping each of the nanostructures and disposed on side surfaces of the nanostructures, and an isolation feature disposed on an edge of the fin base. The edge of the fin base from top to bottom tilts inwardly towards the fin base. In some embodiments, a top portion of the edge of the fin base is substantially vertical. In some embodiments, the semiconductor device also includes a capping layer disposed on a top surface of the isolation feature, and a dielectric layer disposed on the capping layer. The capping layer, the dielectric layer, and the top surface of the isolation feature seal a void under the capping layer.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method, comprising:
forming a fin protruding from a substrate, the fin including an epitaxial stack over a fin base and a hard mask layer over the epitaxial stack, the epitaxial stack including first and second semiconductor layers of different material compositions;
performing a first etching process to etch the hard mask layer, the first etching process including applying a first combination of etchants;
performing a second etching process to etch the epitaxial stack, the second etching process including applying a second combination of etchants; and
performing a third etching process to etch the fin base, the third etching process including applying a third combination of etchants,
wherein the first, second, and third combinations of etchants are different from each other.

2. The method of claim 1, wherein the first combination of etchants includes CHF₃ and SO₂, the second combination of etchants includes CF₄, and the third combination of etchants includes CH₂F₂, SF₆, and CH₃F.

3. The method of claim 1, wherein:
the first etching process includes applying a first transformer-coupled capacitive tuning (TCCT) parameter,
the second etching process includes applying a second TCCT parameter,
the third etching process includes applying a third TCCT parameter, and
the first TCCT parameter is different from the second and third TCCT parameters.

4. The method of claim 3, wherein the second and third TCC parameters have a same value.

5. The method of claim 3, wherein the first TCCT parameter is smaller than the second and third TCCT parameters.

6. The method of claim 3, wherein the first TCCT parameter is in a range between 0 and 2, and the second and third TCCT parameters are in a range between 2 and 4.

7. The method of claim 1, wherein:
the hard mask layer includes a nitride layer and an oxide layer over the nitride layer,
the first etching process includes a first etching step to etch the oxide layer with a first transformer-coupled capacitive tuning (TCCT) parameter and a second etching step to etch the nitride layer with a second TCCT parameter, and
the first TCCT parameter is larger than the second TCCT parameter.

8. The method of claim 7, wherein:
the first etching step includes applying the first combination of etchants,
the second etching step includes applying a fourth combination of etchants, and
the first combination of etchants is different from the fourth combination of etchants.

9. The method of claim 1, wherein:
the third etching process includes a first etching step and a second etching step following the first etching step,
the first etching step includes a first lateral etching rate,
the second etching step includes a second lateral etching rate, and
the first lateral etching rate is smaller than the second lateral etching rate.

10. The method of claim 9, wherein the second etching step increases a concentration of one etchant in the third combination of etchants compared to the first etching step.

11. A method, comprising:
forming a fin protruding from a substrate, the fin including a dielectric portion over a semiconductor portion;
forming a bottom resist layer over the dielectric portion of the fin;
forming a middle resist layer over the bottom resist layer;
performing a first plasma etching process to etch the middle resist layer with a first set of plasma etching parameters;
performing a second plasma etching process to etch the bottom resist layer with a second set of plasma etching parameters; and
performing a third plasma etching process to etch the fin with a third set of plasma etching parameters,
wherein the first, second, and third sets of plasma etching parameters are different from each other.

12. The method of claim 11, wherein:
the first plasma etching parameters includes a first transformer-coupled capacitive tuning (TCCT) parameter,
the second plasma etching parameters includes a second TCCT parameter,
the third plasma etching parameters includes a third TCCT parameter, and
the first TCCT parameter is different from the second TCCT parameter and different from the third TCCT parameter.

13. The method of claim 12, wherein the second TCCT parameter equals the third TCCT parameter.

14. The method of claim 12, wherein the second TCCT parameter is different from the third TCCT parameter.

15. The method of claim 11, wherein:
the third plasma etching process includes a first plasma etching step to etch the dielectric portion of the fin with the third set of plasma etching parameters,
the third plasma etching process includes a second plasma etching step to etch the semiconductor portion of the fin with a fourth set of plasma etching parameters, and
the third set of plasma etching parameters is different from the fourth set of plasma etching parameters.

16. The method of claim 15, wherein the second plasma etching step includes etching the semiconductor portion of the fin with a first lateral etching rate and etching the semiconductor portion of the fin with a second lateral etching rate that is larger than the first lateral etching rate.

17. The method of claim 11, wherein the performing of the third plasma etching process creates an edge of the fin, and the edge of the fin from top to bottom tilts inwardly towards the fin.

18. A semiconductor device, comprising:
a fin base protruding from a substate;
a plurality of nanostructures vertically suspended above the fin base;
a gate structure wrapping each of the nanostructures and disposed on side surfaces of the nanostructures; and
an isolation feature disposed on an edge of the fin base,
wherein the edge of the fin base from top to bottom tilts inwardly towards the fin base.

19. The semiconductor device of claim 18, wherein a top portion of the edge of the fin base is substantially vertical.

20. The semiconductor device of claim 18, further comprising:
a capping layer disposed on a top surface of the isolation feature; and
a dielectric layer disposed on the capping layer,
wherein the capping layer, the dielectric layer, and the top surface of the isolation feature seal a void under the capping layer.
